(19) United States
(12) Patent Application Publication
(10) Pub. No.: US 2025/0035473 A1
(43) Pub. Date: Jan. 30, 2025

(54) ADHESIVE DISPENSING SYSTEMS AND METHODS

(71) Applicant: 3M INNOVATIVE PROPERTIES COMPANY, St. Paul, MN (US)

(72) Inventors: Joerg Hahn, Bad Neuenahr-Ahrweiler (DE); Knut Schumacher, Neuss (DE); Benjamin Muenstermann, Duisburg (DE); Robert J. Bialluch, Willich (DE); Waleri Wischnepolski, Neuss (DE); Christian Weinmann, Alsdorf (DE); Michael Bahners, Neuss (DE); David M. Rudek, Duesseldorf (DE); John A. Merchant, Apple Valley, MN (US); Alissa P. Wenner, Woodbury, MN (US); Patrick G. Zimmerman, Mendota Heights, MN (US); Vincent Jusuf, Minneapolis, MN (US); Kyle R. Hubbs, North Oaks, MN (US); Max Kontak, Ratingen (DE); Brijesh Gupta Chagi Ramesh, Dusseldorf (DE); Robert J. Koch, Wuppertal (DE); Andreas M. Geldmacher, Dormagen (DE); Marcus Saurborn, Essen (DE); Kalc C. Vang, Oakdale, MN (US)

(21) Appl. No.: 18/717,047

(22) PCT Filed: Dec. 9, 2022
(86) PCT No.: PCT/US2022/052343

§ 371 Date: Jun. 6, 2024

Related U.S. Application Data
(60) Provisional application No. 63/265,212, filed on Dec. 10, 2021.

(51) Int. Cl. G01F 1/64; G01K 13/02; G01N 27/07; G01N 27/08

(52) U.S. Cl. CPC G01F 1/64; G01K 13/026; G01N 27/07; G01N 27/08

(57) ABSTRACT

An electrical property sensor is presented that includes a printed circuit board with a first face separated from a second face by a thickness, the first face having a length and a width. The sensor also includes an aperture extending from a first face of the printed circuit board to a second face of the printed circuit board. The aperture includes a receiving electrode and a transmitting electrode. When a fluid flows through the aperture and a voltage is provided at the transmitting electrode, a cunent flow is measured at the receiving electrode.

### BACKGROUND

Systems for dispensing adhesives typically include an inlet or internal area for holding the adhesive, and an output or tip through which adhesive is dispensed to a surface. The flow rate of the adhesive can be directly controlled to meet needs of downstream manufacturing processes by using metering systems. Many systems dispense multiple components that mix together in a mixing chamber. There is a general need to more accurately measure mixing quality and other dispensing parameters in a timely and cost-effective manner.

### SUMMARY OF THE DISCLOSURE

An electrical property sensor is presented that includes a printed circuit board with a first face separated from a second face by a thickness, the first face having a length and a width. The sensor also includes an aperture extending from a first face of the printed circuit board to a second face of the printed circuit board. The aperture includes a receiving electrode and a transmitting electrode. When a fluid flows through the aperture and a voltage is provided at the transmitting electrode, a current flow is measured at the receiving electrode.

Systems and methods including such sensors allow for direct contact between the sensor and a fluid flowing through a dispenser as sensors herein are cost effective to manufacture and can be discarded after use. Systems and methods herein also allow for multiple sensor signals to be gathered across a fluid flow, providing real-time information about materials going into, and out of, a mixing area. Systems and methods herein also allow for bubble detection and removal. Systems and methods herein allow for dispensing systems and their operators to change operational parameters during an operation to address issues as they are occurring, or potentially before they occur, such that less material is wasted and more accurate dispensing is possible.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples may be used in various combinations. In each instance, the recited list serves only as a representative group and should not be interpreted as an exclusive list. Thus, the scope of the present disclosure should not be limited to the specific illustrative structures described herein, but rather extends at least to the structures described by the language of the claims, and the equivalents of those structures. Any of the elements that are positively recited in this specification as alternatives may be explicitly included in the claims or excluded from the claims, in any combination as desired. Although various theories and possible mechanisms may have been discussed herein, in no event should such discussions serve to limit the claimable subject matter.

### BRIEF DESCRIPTION OF FIGURES

FIG. 1 illustrates an adhesive dispenser in which example embodiments can be implemented.

FIGS. 2A-2C illustrate a parallel PCB material measurement flow sensor.

FIGS. 3A-3B illustrate a single PCB material measurement flow sensor in accordance with embodiments herein.

FIGS. 4A-4E illustrate a sensor arrangement in a dispenser in accordance with embodiments herein.

FIG. 5 illustrates a method of forming a sensor system in accordance with embodiments herein

FIGS. 6A-6B illustrate material measurement flow sensors as used in accordance with embodiments herein.

FIG. 7 illustrates a material measurement flow system in accordance with embodiments herein.

FIG. 8 illustrates a method of removing an entrained air bubble from a fluid line in accordance with embodiments herein.

FIG. 9A-9F illustrates a material characterization system in which example embodiments can be implemented.

FIGS. 10A-B and 11A-11B illustrate example conductivity signals that may be received from embodiments herein.

FIGS. 12A-B illustrates an example system for detecting entrained air in a material dispensing system in accordance with embodiments herein.

FIGS. 13A-F illustrate a stack of PCB electrodes in accordance with an embodiment herein.

FIGS. 14A-14B illustrate an example batch detail detection for a material dispensing system.

FIG. 15 illustrates a method of using a material measurement flow sensor in accordance with embodiments herein.

FIG. 16 illustrates a dispensing system in which example embodiments can be implemented.

FIGS. 17A-C illustrates a conductivity measurement system in an example network architecture.

FIGS. 18-20 illustrate example computing devices that can be used in embodiments herein.

FIGS. 21A, 21B, and 22 illustrate sensor constructions described further in the examples.

FIGS. 23-24 illustrate data discussed further in the EXAMPLES.

### DETAILED DESCRIPTION OF ILLUSTRATIVE EMBODIMENTS

The present disclosure relates to sensors that can determine properties of fluids and to methods for determining properties of fluids. The disclosure also relates to data sets received by such sensors and methods of using said data for analyzing said fluid properties.

Many industrial processes use liquid materials such as liquid adhesives, liquid food ingredients, liquid coolants, or liquid reaction products, to name a few examples. Certain properties of such liquids vary over time: adhesives may cure, an oil may become less viscous as temperature rises, a coolant may age and have a lower heat capacity than initially.

Many industrial processes, however, rely on certain properties of a liquid being within a specified range or being unchanged compared to the property in an initial state. For example, adhesives, or adhesive mixtures, may have different curing properties when applied at different temperatures, different mixing ratios, etc.

Co-pending international application IB2021/056362, filed on Jul. 14, 2021, discloses a property sensor for determining a property value of a liquid that includes two PCBs that define a channel through which the liquid flows. While this allows for direct contact between the sensor and the fluid, there exists a need for cost-effective sensors that can provide more contextual information about material mixing. Embodiments herein provide systems and methods for effectively and accurately measuring material information in mixing contexts.

Described herein are sensors and sensor systems that are used to measure electrical properties of fluids. Broadly sensors herein function by a transmitting electrode receiving a voltage, which creates an electrical field. As a fluid flows between the transmitting electrode and a receiving electrode, it conducts a current to the receiving electrode. The term “sensor” as used herein may refer both to the physical sensor that provides a sensor signal indicative of conducted current, as well as to a “sensor system” that includes a processor that calculates an electrical property of the fluid based on the sensor signal.

The term “electrical property” is intended to broadly refer to any electrical property of a fluid that can be derived based on impedance measurements of a sensor. Used herein, for ease of understanding the embodiments, are the example of impedance measurements. However, it is expressly contemplated that other electrical properties may be calculated and relevant to embodiments herein. For example, conductivity measurements or dielectric constants may also be determined from impedance measurements. Either conductivity or dielectric constant may be relevant, as illustrated herein, for determining relevant functionality of a dispensing system or quality of fluids flowing therein.

As described herein, sensors are described as measuring electrical properties of “fluids.” The term “fluid” is intended to be interpreted broadly and is intended to cover liquids with low viscosities, liquids with high viscosities, semi-solid materials, suspensions, melted materials, or other flowable materials.

Sensors are described herein as having one or more “apertures” within a “printed circuit board.” These terms are intended to be interpreted broadly. For example, an aperture may fully extend through a thickness of a sensor along part of, or the entirety of its length. Apertures may have beveling along part or all of a perimeter. An aperture may be elongated, such as a slot, or may be shaped, such as a circular or ovular hole. An aperture may have one or more corners or edges, or may have curvature along part or all of its perimeter. As used herein, a “printed circuit board” refers to a laminated sandwich structure of conductive and insulating layers. Printed circuit boards (PCBs) herein may include any number of terminals and conductors that allow for voltage to be applied to a transmitting electrode and for current to be transmitted from a receiving electrode. PCBs may be manufactured using traditional PCB manufacturing technology or additive manufacturing technology. As used herein, PCB is intended to cover any number of layers, with or without an edge connector. Any suitable conductive metal may be used to form conductive layers. Any suitable insulating material may be used to form insulating layers.

Property sensors as described herein may be used to sense properties of a fluid resulting from a mixing process. They may also be used to sense properties of input fluids for a mixing process or for an industrial manufacturing process. Advantageously, separate property sensors for respective input fluids are placed just in front of the mixer. Data from these property sensors measuring the input fluids can be processed along with data from a property sensor measuring the mixed fluid, e.g. in an integrated materials property monitoring system. Where, for example, a fluid composition is mixed from three input fluids, a property of each of the three fluids before mixing can be determined using three property sensors at the respective outlets of the three containers containing the three input fluids. This may help in quality control and reduce waste that might otherwise occur due to one of the input fluids being outside a specification for the property.

Sensors described herein may determine various properties of a fluid, like, for example, mixing ratio of a two-component adhesive or curing status of a curable composition or ageing status. The number of properties which were varied previously to establish the set of calibration data representing calibration impedance responses measured previously at the different property values determines the number of properties that can later be determined by the property sensor. The pre-stored set of calibration data representing calibration impedance responses measured previously at the one or more sensing frequencies and at different property values of a property of the fluid forms, or represents, a multi-dimensional data field which is specific for the fluid. This data field allows the property value deriver to determine, from a response impedance actually measured, a value of the property of the fluid.

A fluid has many properties: for example, viscosity, density, color, content of volatile components, water content, chemical composition, boiling point, but also ageing status, curing status in case of fluid curable compositions, or mixing ratio in case of the fluid being a mixture, to name only some.

Further, certain properties of certain fluids, however, vary with time and/or with other parameters such that the response impedance in a property sensor described herein varies with time and/or with the other parameters, too. Values of these properties may be derived via sensors and systems described herein. Additionally, variation with time includes variation of the property between different production lots of the fluid. The property sensor described herein can thus be used to detect differences in a certain property (e.g. chemical composition) of a suitable fluid between a later production lot and an earlier production lot of the fluid.

The term “property” of the fluid, according to the present disclosure, is not particularly limited. For example, as described in embodiments herein, one property of interest is a mixing ratio of two or more components of the fluid. In certain of these embodiments, the fluid is a two-component adhesive, and a property of the fluid is a mixing ratio of the components. In other embodiments, a property of interest is a curing degree or a curing status. In certain of these embodiments the fluid is a curable composition, and a property of the fluid is the degree of curing of the composition.

In other embodiments, a property of interest is an ageing degree or an ageing status. In certain of these embodiments the fluid is an ageing fluid, i.e. a fluid in which certain characteristics change over time once the ageing fluid has been created. The property sensor may determine a change in the response impedance of the ageing fluid after some ageing, compared to response impedances of an identical fluid recorded before ageing and at certain times after ageing. The property sensor may thereby determine an ageing degree or an ageing status of the fluid.

A property of the fluid may take different values, such as, for example, a property “dynamic viscosity” of the fluid “water” can take values like 1.30 mPa·s or 0.31 mPa·s. Such values are referred to herein as property values. Certain properties may not be related to only numerical property values. A property “curing degree”, for example, may have property values like, for example, “uncured”, “partially cured” or “fully cured”. A property “curing status”, for example, may have property values like, for example, “uncured” or “fully cured”. A fluid according to the present disclosure may be a viscous fluid. Independent of its viscosity, the fluid may be a flowing fluid. The fluid may be a continuously flowing fluid.

In certain embodiments, a fluid is a fluid adhesive. In certain of these embodiments, a fluid is a curable fluid adhesive. In certain of these embodiments, a fluid is a curable two-part fluid adhesive. “Two-part” refers to the adhesive being composed of a first component and a second component which are mixed, e.g. in a static or dynamic mixer, to form the adhesive.

In other embodiments, the fluid is, or comprises, a void filler, a sealant, a dielectric fluid such as a 3M™ Novec™ engineered fluid, a thermally conductive interface material such as a thermally conductive gap filler, or a fluid chemical composition to produce any of the aforementioned fluids.

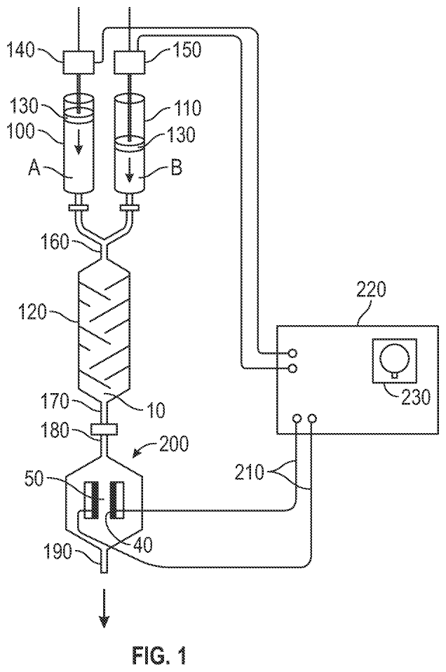

FIG. 1 illustrates an adhesive dispenser in which example embodiments can be implemented. FIG. 1 is a side view of a dispenser and mixing system for a viscous two-component adhesive. First component A and second component B of the adhesive are pushed out of respective cartridges 100, 110 into and through a static mixer 120. In the illustrated system 1, at the output 170 of the static mixer, the mixed adhesive passes through a sensing area 50 before being dispensed at the output 190. Sensing area 50 may house a sensor that senses a mixing ratio of components A and B in the mixed adhesive.

The cartridges 100, 110 contain the viscous components A and B, respectively. A respective piston 130 is moved further into the cartridge 100, 110 and pushes the component A, B out. The pistons 130 are driven by respective motors 140, 150 which are individually controllable, and the pressure generated by the pistons 130 moves the unmixed components and—after mixing—the mixed viscous adhesive 10 through the static mixer 120 and the channel 200 of system. The motors 140, 150 may be part of a feedback loop: if a sensed mixing ratio is outside an acceptable band of desired mixing ratios, the motors 140, 150 can be individually controlled such as to push more of component A and/or less of component B (or vice versa) into the static mixer 120 in order to adjust the mixing ratio towards the desired mixing ratio. Both motors 140, 150 can be controlled separately to obtain a desired total throughput per second of mixed adhesive to be dispensed.

The static mixer 120 receives the unmixed components A and B of the two-component adhesive at an input end 160. Lamellae inside the static mixer 120 redirect the flow of the input materials many times and introduce shear forces that help mix the components A and B with each other. The output end 170 of the static mixer 120 is connected to an inlet 180 of a duct piece 200 (shown in longitudinal sectional view) containing a channel and sensing zone 50. The mixed adhesive 10 can thus exit the static mixer 120 and enter the duct piece 200. At the outlet 190 of the duct piece 200, the mixed adhesive is dispensed.

Within sensing area 50 may be a sensing system that is communicable, for example via wires 210 to a computerized control system 220, which provides an AC voltage to generate a required electric field needed for measuring conductivity using a suitable sensing system, such as that described herein.

The computerized control system 220 has an internal data storage device 230, on which a set of calibration data representing calibration impedance responses is stored. These calibration impedance responses may have been previously recorded, i.e. before the measurements, in a calibration process using the same duct piece 200 and identical components A, B resulting in an identical mixed viscous adhesive 10. During the calibration process the mixing ratio A/B was adjusted to certain fixed calibration mixing ratios (CMR), and for each of these calibration mixing ratios the calibration impedance response (CIR) was sensed at five different calibration sensing frequencies (CSF). These data sets, e.g. in the form of triples of (CMR, CSF, CIR), are recorded and stored in datastore 230. They form a three-dimensional data field, which is specific for the viscous adhesive. The data sets are used to build a parametrized multi-dimensional model, based on multi-dimensional polynomials, of the data sets. This parametrized model facilitates quick interpolation by a computer between individual data sets and quick derivation of a property value of a property of the fluid in the subsequent measurement. The parameters of the parametrized model form a set of calibration data which represents the data sets recorded during the calibration process.

Later, when running an actual measurement of the value of the property “mixing ratio” of a viscous two-component adhesive of components A and B in system 1, the measured impedance responses (MIR), each measured at certain measurement sensing frequencies (MSF), are recorded in the control system 220. In order to derive a value for the mixing ratio from the measured impedance responses at the measurement sensing frequencies, software running on the control system 220 identifies, within the set of calibration impedance response triples, those triples having the closest calibration response impedances, closest to the measured impedance responses, and the closest calibration sensing frequencies, closest to the measurement sensing frequencies. This identification and a potential interpolation can be performed easily by using the parametrized multi-dimensional polynomials modelling the plurality of data sets, i.e. the plurality of triples of (CMR, CSF, CIR). From those calibration data, the software derives a value for the (sofar unknown) mixing ratio in the actual measurement.

The same sensing frequencies used for calibration will often be used also for the measurement. There may, however, occur a mixing ratio in the measurement for which no calibration impedance response had been determined in calibration. So there may be not an exact match in both sensing frequency and response impedance between a triple in the calibration data set. In such a case, an interpolation between two suitably chosen calibration triples, containing two calibration impedance responses close to the measured response impedance, yields an interpolated calibration mixing ratio which can then be considered the mixing ratio in the measurement. The interpolation is performed by software on the control system 220, using the parametrized multi-dimensional polynomials.

The result of the interpolation and derivation is a value of the mixing ratio of components A and B in the mixed two-component adhesive 10 in the sensing zone 50 during the measurement.

In the present embodiment, the calibration impedance responses were measured in their dependence on two parameters, namely on the sensing frequency and on the mixing ratio. In other embodiments, dependence of impedance responses on further parameters may be taken into account, such as, for example, dependence on the temperature of the adhesive in the sensing zone. A data set of the calibration impedance responses would then be a quadruple of values, such as (CMR, CSF, CIR, Temperature), and the pre-stored set of calibration impedance responses would be a set of quadruples forming a four-dimensional data field, which is specific for the viscous adhesive. Taking further parameters into account could make a data set be a quintuple of values, or high-order tuples of values, so that the data sets of calibration impedance responses is a multi-dimensional data field of more dimensions and can be represented by different parametrized multi-dimensional polynomials.

Control system 220 may record the values for mixing ratio, with a time stamp, for quality assurance. In the illustrated system, motors 140, 150 pushing the respective components A and B into the static mixer 120 are connected to, and controlled by, control system 220. The mixing ratio derived during the actual measurement is checked continuously against a desired mixing ratio. If its deviation from the desired mixing ratio is larger than acceptable, control system 220 may change the speed of one or both of the motors 140, 150 suitably to adjust the measured mixing ratio towards the desired mixing ratio. While motors 140, 150 are illustrated, it is expressly contemplated that systems and methods herein may also apply to compressed air operated dispenser systems, hydraulic systems, cavitation-based systems, precision gear-based systems, peristaltic pump-based systems, or other suitable dispensing systems.

FIG. 1 illustrates an example system where a sensing area 50 is located after the mixer 120. However, it is expressly contemplated that, in some embodiments, a sensing area 50 may be positioned before mixer 120, for example positioned to measure a parameter relevant to only material A or B, or elsewhere in the system, for example within mixer 120 to measure a mixing progress.

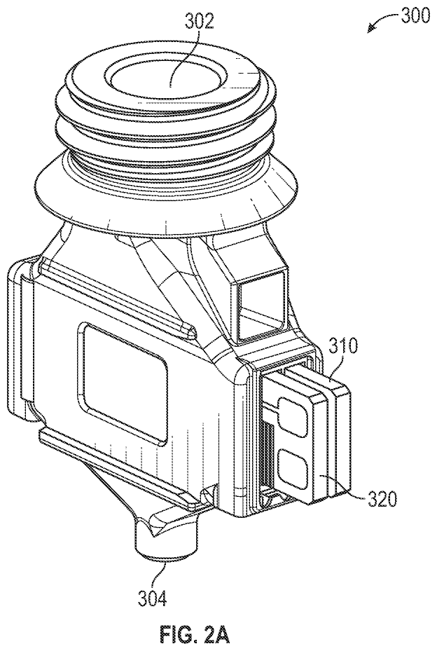

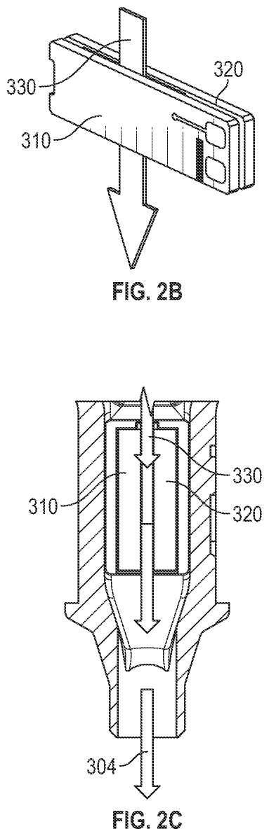

FIGS. 2A-2C illustrate a parallel printed circuit board (PCB) sensor material measurement system. Co-pending PCT application IB 2021/056362, filed on Jul. 14, 2021 describes a material measurement flow sensor such as that illustrated in FIGS. 2A-2C. FIG. 2A illustrates a perspective view of a material measurement system 300. FIG. 2B illustrates a view of a pair of PCB sensors 310. FIG. 2C illustrates a cutaway view of sensing system 300. A sensing system 300 may be, for example, placed within or instead of a sensing area within a dispensing system. Fluid flows from an inlet 302 to an outlet 304, or vice versa. As illustrated in the cutaway view of FIG. 2C, a pair of PCB sensors 310,320 are spaced apart such that fluid can flow through channel 330. As fluid flows through channel 330, it passes between PCBs 310, 320. The PCB boards each serve as an electrode, allowing for a conductivity measurement to be taken. By measuring conductivity over time, an understanding of how the mixing ratio varies when in use (e.g. during steady state operation, at start up, after a pause) is possible. This can provide important feedback if a mixing ratio falls outside of an acceptable range. The mixing ratio may be adjusted, either automatically or manually in response to an alert, and any adhesive, for example, dispensed when the mixing ratio was outside of acceptable ranges may be discarded. Similarly, it may be possible to detect that partial curing has occurred and that a system purge is needed.

However, while system 300 can be in direct contact with a fluid and obtain conductivity measurements over time, system 300 only provides one measurement at a time as fluid flows through the channel.

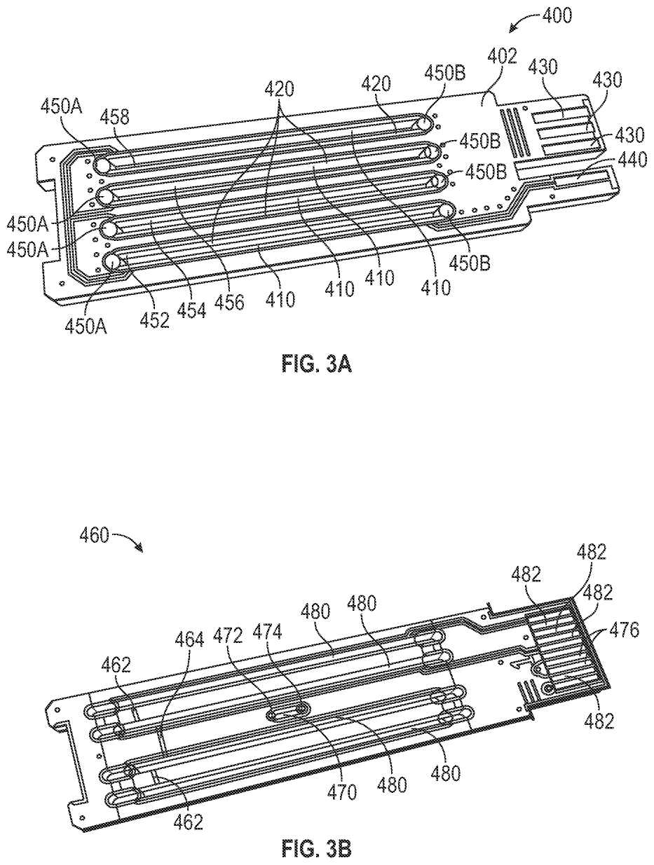

System 300 utilizes two PCBs to serve as electrodes, one positive, and one negative, to collect a single conductivity measurement for a fluid flow. This gives a snapshot of fluid conditions. Systems and methods provided herein, and discussed in FIGS. 3-8, utilize a sensing system capable of using less material and potentially provide a fuller picture of fluid flow conditions. A single PCB serves as housing for both positive and negative electrodes along one or more slits. This provides multiple benefits including pressure independence—system 300 requires optimization to handle pressure changes in a housing and bending of PCB boards under fluid pressure. The pressure drop experienced across the thickness of a PCB board, instead of the width, will only have a minor influence. Similarly, the temperature dependency is also less for system 400 than system 300 as PCB material is already optimized for electronics with a low thermal coefficient of expansion. From a material use standpoint, the ability to use only one PCB to obtain measurements is also an improvement as it results in only one PCB board used, instead of two, if material curing occurs. This also reduces the cost to produce sensing system 400. Further, system 400 can provide multiple conductivity measurements, providing a better indication of whether mixing is complete across a sensing area.

FIGS. 3A-3B illustrate material measurement flow sensors in accordance with embodiments herein. FIG. 3A illustrates a PCB material measurement flow sensor 400. As illustrated in FIG. 3A, a sensing system 400 includes a PCB board 402 with one or more grounds 430 and a TX contact 440. The TX contact provides a transmitting signal to each transmitting electrode 410. Four RX contacts (not shown), located on the reverse side of the PCB, receive the indication of a sensed impedance from each of the electrode pairs. The electrical potential of each receiving electrode 420 is electronically regulated to ground potential separately. The regulator action for each receiving electrode, in some embodiments, is interpreted as an impedance signal for each electrode pair. In the illustrated embodiment, four separate measurements channels can provide information, each through its own TX contact 440 and RX contact (not shown).

In the illustrated embodiment, a sensing system 400 has four electrode pairs, with four transmitting electrodes 410, each paired with one of four receiving electrodes 420. However, it is expressly contemplated that more, or fewer, electrode pairs may be present, depending on available area on a PCB board and sensing needs.

Each of the electrode pairs are decoupled from the adjacent pair such that four separate conductivity measurements are received, one from each electrode pair 410, 420. Sensing system 400 is placed, in some embodiments, perpendicularly to the flow of material, such that a first sensing area 452 receives a first portion of material flow, a second sensing area 454 receives a second portion of material flow, a third sensing area 456 receives a third portion of material flow, and a fourth sensing area 458 receives a fourth portion of material flow. Therefore, system 400 can simultaneously generate four different signals relative to a single material flow, providing a better picture of whether a mixing ratio (or other measured parameter) is consistent across an entire sensing area.

In comparison to previous sensing systems, such as those of FIGS. 1-2 conductivity measurements required both a positive and a negative pole, which would require two PCBs per electrode pair. System 300 could be modified, but would require 5 PCB boards in a stack, with precise spacing between each adjacent PCB board. In contrast, system 400 allows for four measurements to be taken simultaneously with a single PCB. It also provides a larger surface area for material flow, through a shorter sensor distance.

FIG. 3A illustrates an embodiment where each electrode pair is part of a slot 452, 454, 456, 458. However, it is also contemplated that, instead of being closed on both sides, a sensing area may include a pair of electrodes on a protrusion, or within an aperture, in a “comb”-like structure. However, it may be preferred for both ends to be closed from a structural standpoint, especially with viscous fluids.

As described further herein, the electrodes 410, 420 may be formed by metallization on the interior surface of slides 452, 454, 456, 458, using copper for example. The metallization process may cause electrodes 420 to be connected to electrodes 410. Therefore, a decoupling or disconnecting step is needed. This can be done by breaking the connection, for example by drilling a hole in the positions 450A and 450B as illustrated, by punching out a perforated component, milling, nibbling, etching, laser cutting or another suitable method.

Systems and methods herein may be used for a variety of materials being dispensed. PCB boards often have a maximum operating temperature less than 170° C., which limits the temperature of materials that can be dispensed through a sensor system 400. Materials may have a range of viscosities, for example up to around 10⁵ Pa s. Higher viscosity might result in a dispensing pressure being insufficient to force the material through slots 452-458 without breaking the sensor. However, higher viscosity materials may be accommodated by increasing the width of slots 452-458. However, sensing system 400 may be less sensitive. Similarly, for materials with particulates, such as suspensions for example, particle sizes have to be smaller than the width of slots 452-458. Additionally, systems herein may be limited to solvents that do not cause corrosion or otherwise damage the PCB 402 or electrodes 410, 420.

FIG. 3B illustrates another embodiment of a sensing system 460, which includes a built-in temperature sensor 470. Temperature sensor 470 sits within a slot with a connection point 472 for a ground signal and a connection point 474 for a temperature signal. Ground signal connection point 472 connects to a ground signal communicator 482. Temperature signal communication point 474 connects to a temperature signal communicator 476. Similar to the embodiment of FIG. 3A, four impedance or conductivity sensor slots 480 are also present, each connected to a ground signal 482. However, it is noted that two different spacings between slots are present in the embodiment of FIG. 3B. A first spacing, 462 is present between a first and second slot 480, and between a third and fourth slot 480, while a second spacing 464 is present between second and third slots 480. Increased spacing 464 may provide improved shielding against interference between electromagnetic fields generated by each electrode pair.

Many mixing processes are at least partially temperature dependent, with material properties like viscosity changing with temperature. Temperature sensors inserted from an external point are often fragile and need to be in the middle of the flow of the material being tested. In the embodiment of FIG. 3B, a temperature sensor is sealed within a housing, which keeps it isolated from the material. The seal layer may be a layer of varnish, for example, which may allow for the thermal contact to be improved relative to other housing materials. As illustrated, the temperature sensor connects via contacts 482 on the edge connector.

FIGS. 3A-3B illustrates an embodiment where slots 452-458, 470 and 480 are ovular in shape, with a generally straight body and rounded ends. However, other configurations are possible. Electrodes 410, 420 may be curved, for example, or otherwise shaped to accommodate an available volume of a dispensing system.

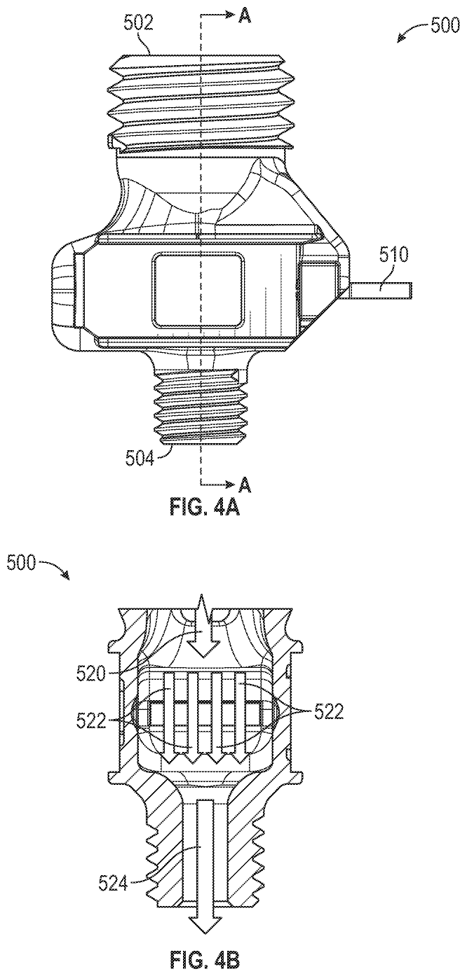

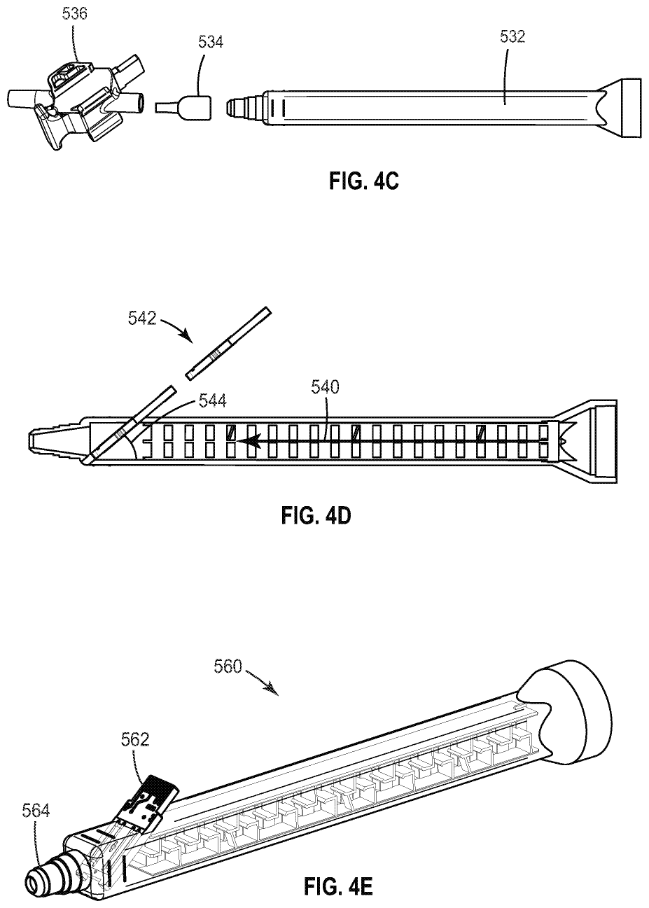

FIGS. 4A-4C illustrate a sensor arrangement in an adhesive dispenser in accordance with embodiments herein. FIGS. 4A-4C illustrate an embodiment where four electrode pairs are present on a single PCB. However, as discussed herein, it is expressly contemplated that more, or fewer, electrode pairs may be used.

A sensor housing may couple to a fluid container, e.g. at the bottom of cartridge 100 or 110 of the dispenser illustrated in FIG. 1, or at the end of mixer 120, for example.

A material mixture may enter sensor housing 500 at input 502, and may exit at output 504. A sensing system 510 may be received by, or positioned within sensing area 500. In some embodiments, sensing system 510 is a replaceable sensing system that can be removed from housing 500 when an operation is complete. In some embodiments, housing 500 includes a self-sealing material to seal sensing system 510 in place. In some embodiments, an O-ring, gasket, or other compressible material is used as a seal. However, it is also expressly contemplated that sensing system 510 may be integrated into housing 500 or sealed into housing 500 such that it is not removeable, for example using adhesive.

Sensing system 510 may be a PCB with a number of slots, protrusions, or apertures, each of which may include a pair of electrodes that can sense a conductivity of the material mixture when in direct contact with the material mixture. As illustrated in FIG. 4B, a cross-sectional view of the sensing area 500 of FIG. 4A, a material stream 520 may be forced through a number of channels 522, each of which includes a transmitting and receiving electrode and, therefore, can take a separate conductivity measurement of the material flow. A recombined material stream 524 may exit sensing area 500 through outlet 524.

Sensing area 500 may receive sensor system 510, for example in a slot as illustrated in FIG. 4A. However, other configurations are possible. Sensor system 510 may be a single use sensor system, discarded after use in the event that a material flow cures or otherwise degrades components of system 510.

FIG. 4C illustrates a sensor system. The sensor system has a connector 534 that connects a dispenser 532 to a sensor unit 536. FIGS. 4D-4E illustrate cross-sectional views of a dispensing system, for example similar to system 530.

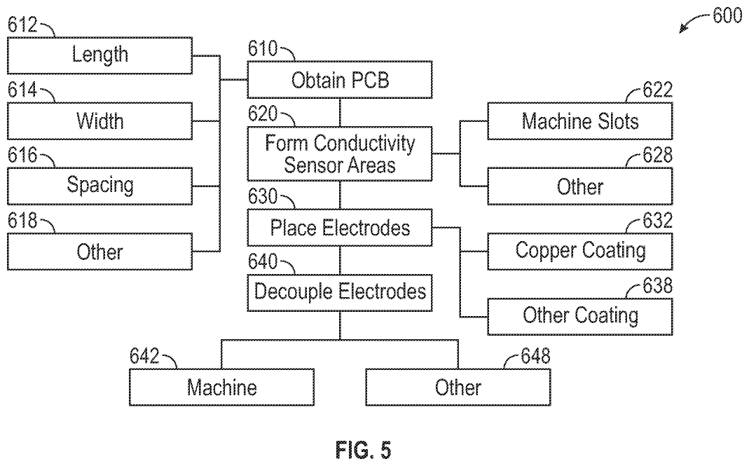

FIG. 4D illustrates the insertion angle 544 of a PCB 542 once inserted. PCB 542a may be any of the sensor configurations described herein, or another suitable sensor configuration. Insertion angle 544 is 90°, in some embodiments. As illustrated in FIG. 4D, in some embodiments insertion angle 544 is about 45°, with respect to a mixing column flow direction 540, or about 30°, in some embodiments, or about 60° in some embodiments, or about 75° in some embodiments, or about 15°, in some embodiments. FIG. 5E illustrates a perspective view of a dispenser 560 with mixing chambers that cause mixing of two or more components prior to the mixture passing through PCB sensor 562, and through dispensing nozzle 564.

As illustrated in FIG. 4D, PCB 542 may interact with sensor housing (e.g. 536) by being guided into place using a slider element inside a molded tool. In some embodiments, PCB 542 removably slides into place into a dispenser housing. However, in other embodiments, PCB 542 is sealed into place. This may be advantageous for particularly viscous mixtures that could otherwise force PCB 542 out of position.

The exemplary embodiments illustrated in FIGS. 4C-4E concern a PCB-based impedance sensor that can be attached to a static mixer, using an adapter or other connection mechanism, providing mix ratio information in real time. The use of an adapter that can receive a PCB unit allows for compatibility of the PCB sensor with a number of dispensing systems.

Realtime feedback of a mixture moving through a dispensing unit is particularly helpful for quality control purposes, especially for operations with frequent starts and stops, which can cause the mix ratio to drift over time.

The PCB sensor is in a housing that can be coupled to a dispenser. However, it is expressly contemplated that the sensor housing and the mixing chamber are, in some embodiments, a single unit. Such an arrangement produces a single disposable dispensing unit. This is particularly useful for adhesives—such as two-part epoxies, which require a specific mixing device and strict compliance with mixing ratios. While not shown in FIGS. 4C-4E, it is expressly contemplated that a sensing system, such as system 530, may include a temperature sensor, for example on board the PCB sensor.

A unitary disposable sensor unit simplifies the product as connections between parts are reduced and reduces waste in production because fewer parts are required. A disposable “smart” static mixer can be used with a reusable sensor system such that as a first mixer is disconnected from the sensor system and discarded after a first operation, a second static mixture can be connected to the same sensor system.

FIG. 5 illustrates a method of forming a sensor system in accordance with embodiments herein. Method 600 may be used, for example, to form a sensor system such as sensor system 510 or 400, or another suitable sensor system. Similarly, while method 600 may illustrate some ways that sensor systems 400 or 510 may be formed, it is expressly contemplated that said systems may be manufactured according to other suitable methods.

In block 610, a template is obtained. The template may have one or more grounds, one or more contacting electrodes for receiving commands and communicating signals and/or other features. As described herein, in some embodiments, a PCB is used. However, while PCBs are inexpensive, it may be preferable to use 3D-printing technology to form a template. In some embodiments, blocks 610 and 620 are performed simultaneously as a 3D-printed template is constructed with conductivity sensor areas in place.

In block 620, conductivity sensor areas are formed in the template. The conductivity sensor areas may be slots, or apertures in which positive and negative electrodes can be placed or attached. Each area may have a length 612 and a width 614. The width 614 may be selected based on the viscosity or particle size present in a material that will pass through the sensing system, for example. The length 612 may be selected in order to increase a surface area available for sensing conductivity. A spacing 616 between adjacent conductivity sensor areas may also be present. In embodiments where conductivity sensor areas are slots, spacing 616 may be dictated in part by the need for structural soundness of the template when under pressure from a viscous material. Other considerations may also be taken into account, as indicated in block 618.

The conductivity sensor areas may be machined into the template, as indicated in block 622. However, other methods are expressly contemplated, as indicated in block 628.

In block 630, electrodes are placed. In some embodiments, electrodes are placed through a metallization step in which a conductivity sensor area is coated with a metal. It may be a copper coating, as indicated in block 632, or another metal coating, as indicated in block 638. The metal coating may be placed through electroplating, for example, or another suitable connection. However, other electrode placing methods are also possible, such as adhering electrodes in place, for example.

In block 640, in some embodiments, electrodes are decoupled from one another, such that each conductivity sensor area includes a positive and a negative electrode, and that adjacent conductivity sensors are decoupled from one another. In embodiments where electrodes are placed through electroplating, it is necessary to remove unwanted connections between positive and negative electrodes. In some embodiments, the conductive part at the end of each slot is milled out. In some embodiments, each edge is milled out further than the edge of the conductive portion. Because the material exchange occurs perpendicular to the slots, it is slower at the end of each slot. It is preferred to avoid measuring the slower moving material as it may make the measurement inaccurate.

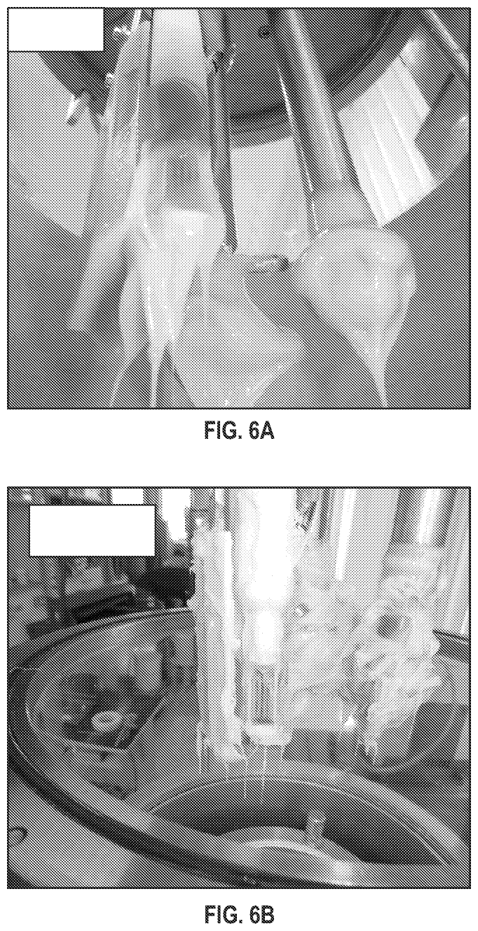

FIGS. 6A-6B illustrate material measurement flow sensors as used in accordance with embodiments herein. As illustrated in both images, sensors according to embodiments herein can be placed in direct contact with a material or fluid, providing a conductivity measurement based on that direct contact. This provides a more accurate measure of mixing ratio than other methods that do not allow for direct contact between a sensor and a material. However, as illustrated in FIGS. 6A and 6B, a sensor is coated with material after use. In scenarios where the material of interest is corrosive, highly viscous or is curable, it is beneficial to be able to discard the sensor after use.

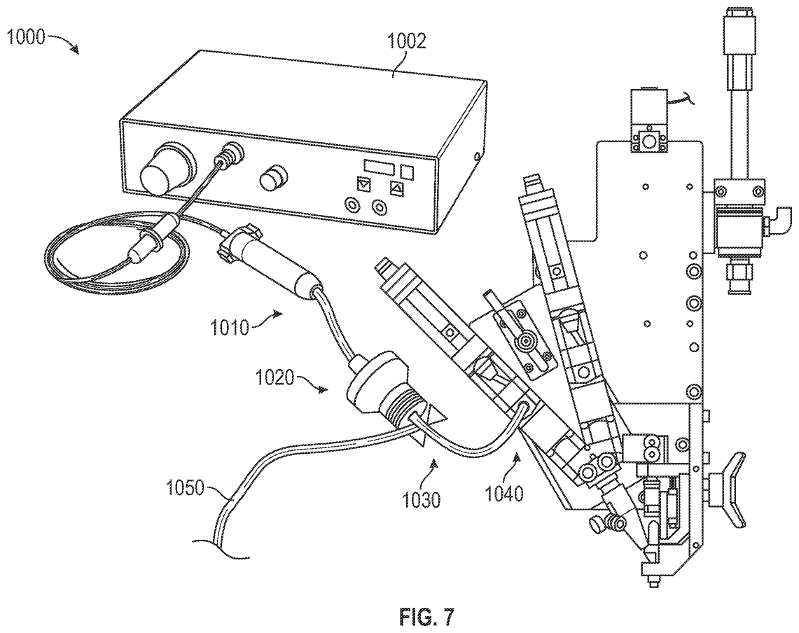

FIG. 7 illustrates another embodiment of a dispensing system in which embodiments herein may be useful. System 1000 illustrates a smaller dispensing system 1000 with a controller 1002, which may include a motor that provides pressure for dispensing a fluid through dispenser 1010. Dispenser 1010 may have entrained air bubbles. In small volumes, the presence of air bubbles can significantly affect the amount of material dispensed by displacing material with air. For a dispensed mixture, this can result in an incorrect mixing ratio being dispensed. For viscous fluids, this may result in an area of a worksurface not receiving dispensed fluid.

It is important to detect, and remove, air from a dispensing system. Therefore, in some embodiments, before reaching a dispensing system 940, material passes through a sensing area 1020, which includes a PCB-based sensor as described herein. The sensor detects an air bubble and, in response, a valve 1030 is opened, allowing for the air bubble to leave through stream 1050. When the air bubble has passed, valve 1030 closes, and the material continues on to dispensing system 1040. In some embodiments, another sensing area 1020 is present after valve 1030 to confirm that the air bubble has been removed. As illustrated in FIG. 7, valve 1030 is located immediately downstream from a sensing system 1020. Valve 1030 automatically opens and closes, in some embodiments, based on an indication from either sensing system 1020 directly, controller 1002, or another controlling system that, based on a conductivity measurement received from system 1020, sends a command to automatically purge the material line.

FIG. 7 is a schematic of a system 1000 with components for one material line clearly illustrated. However, it is expressly contemplated that, as illustrated, a mixture may be formed from two components, and a similar set of components are necessary to provide the second component, free of air bubbles, to a mixing chamber (not clearly shown).

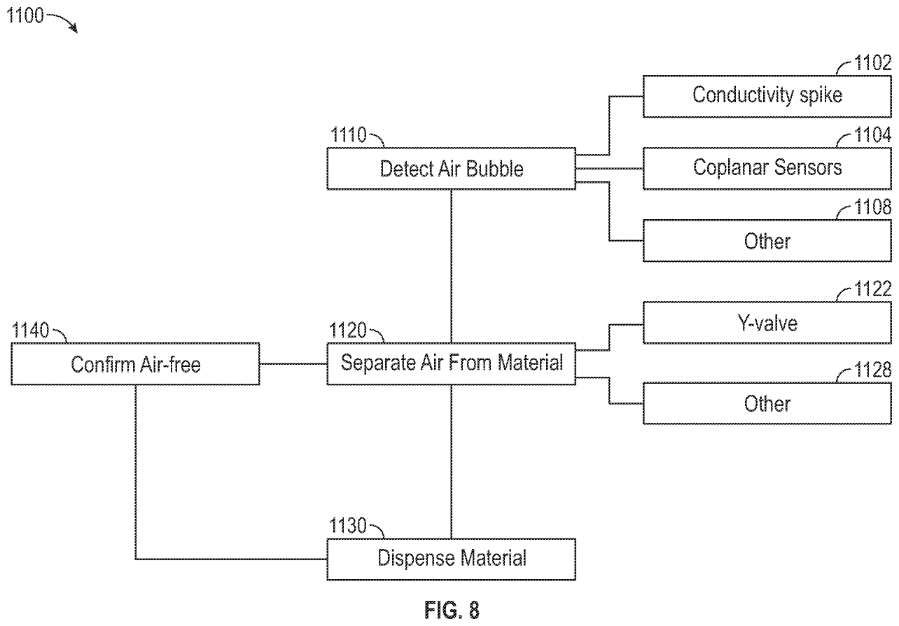

FIG. 8 illustrates a method of removing an entrained air bubble from a fluid line in accordance with embodiments herein. Method 1100 may be practiced using sensor systems such as those described herein, or other suitable sensors. In block 1110, an air bubble is detected using a conductivity sensor in contact with a flowing material. The conductivity sensor may be a disposable sensor intended to be thrown out after use, in some embodiments. The conductivity sensor may include one or more pairs of electrodes in a coplanar arrangement 1104 such that the dispensed material flows through the electrode pairs. The inclusion of multiple electrode pairs helps to detect air bubbles of smaller sizes as they flow through a dispenser. In some embodiments, an air bubble is detected by an identifiable conductivity spike 1102. Other dispenser features are contemplated, as indicated in block 1108.

In block 1120, a detected air bubble is removed from a flowable material. Particularly for mixtures, it is important to ensure that a correct material volume is dispensed. A Y-valve 1122 may be used to divert material flow when an air bubble is detected. Other purge mechanisms 1128 may be used, in some embodiments. In some embodiments, it may be possible to mitigate a detected air bubble without purging, for example by instead sending a signal to the motor controlling fluid flow to increase speed and dispense an amount of material needed to replace the volume of air occupied by the bubble. However, while a detected spike may be proportional to the size of the air bubble, it is not immediately detectable whether the detected air bubble is one large bubble, several smaller ones, etc. Additionally, for embodiments where dispensed fluid must be a certain volume, or have a certain shape, it is preferable to remove the bubble. For example, where dispensed adhesive must be conductive, an air bubble could cause a break in conductivity if dispensed.

In block 1130, material is dispensed. In some embodiments, as indicated in block 1140, it is first confirmed that the material flow is free of air bubbles. T his can be done, for example, using a second conductivity sensor in some embodiments.

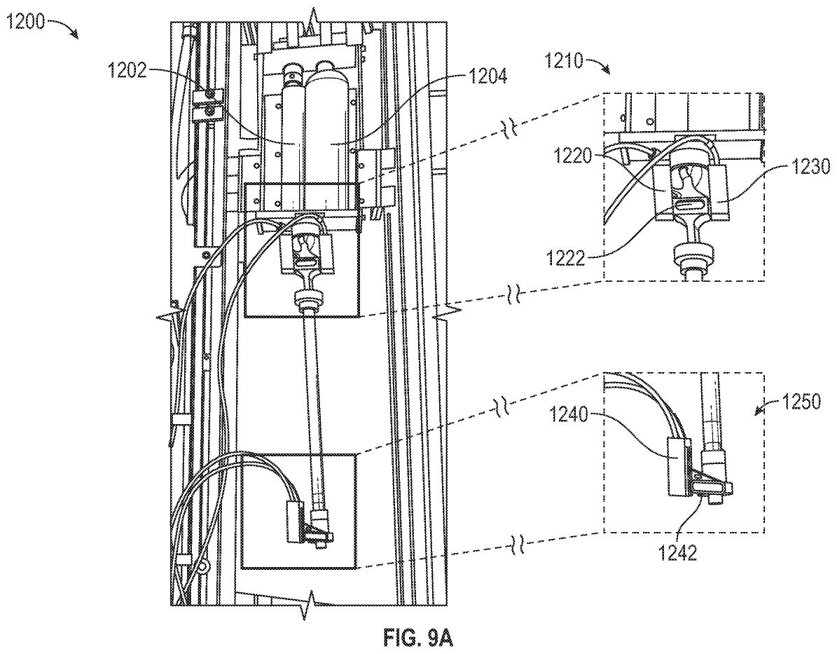

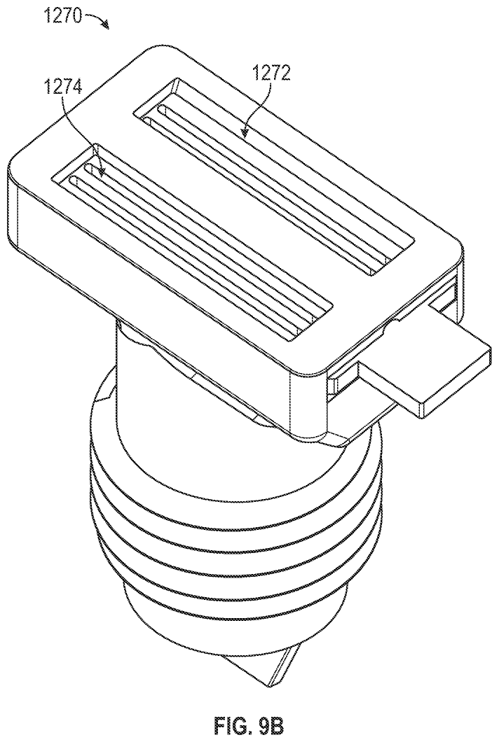

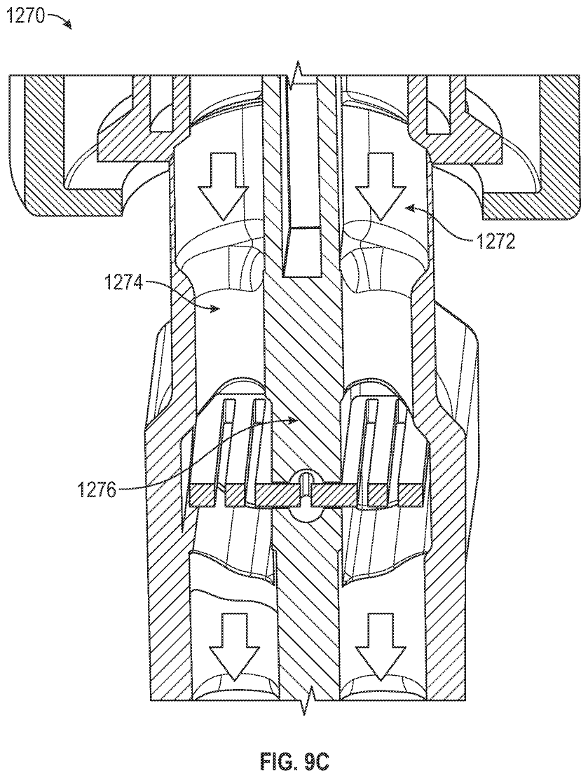

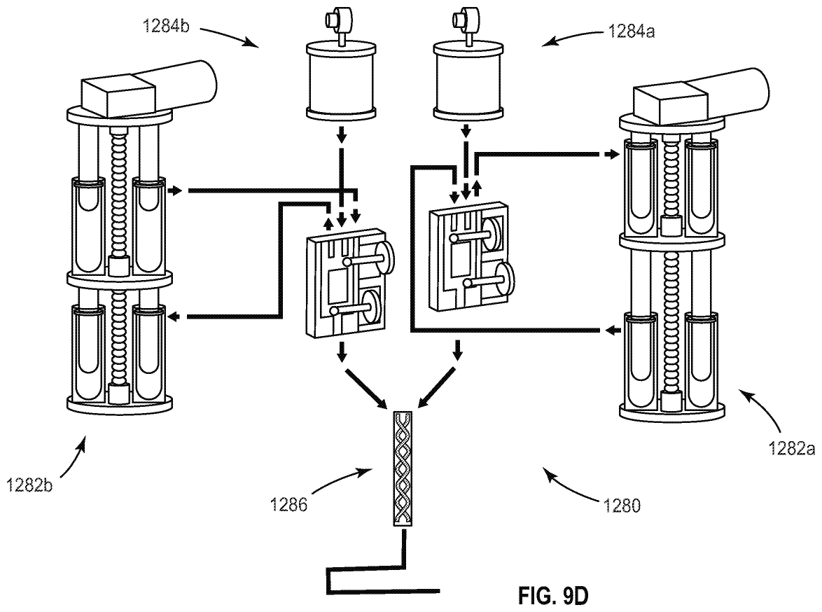

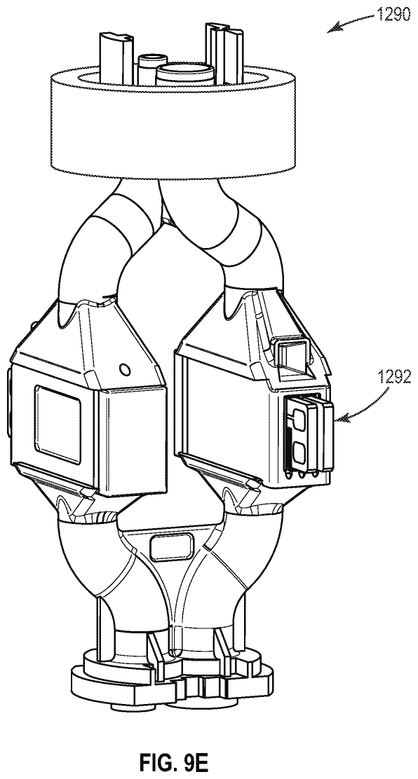

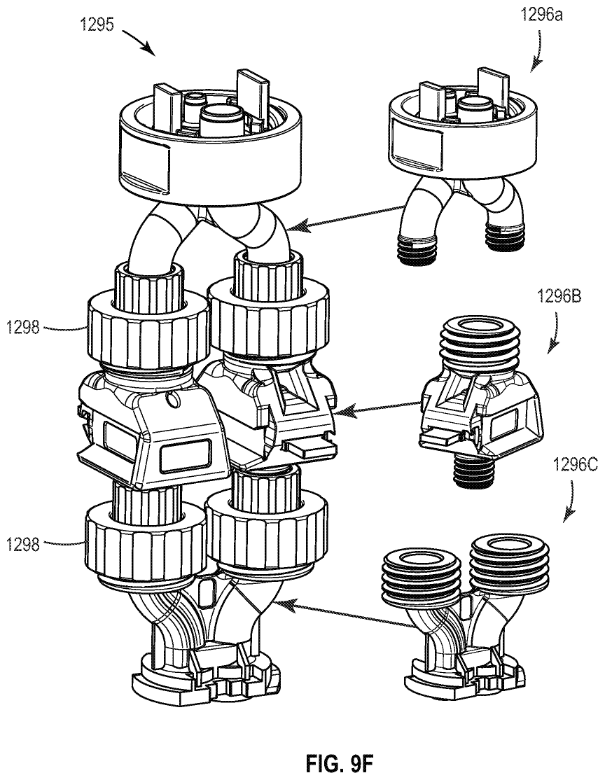

FIG. 9A illustrates a material characterization system in which example embodiments can be implemented. System 1200 is a 2-part material dispenser that is configured to dispense a Part A component 1202 and a part B component 1204. System 1200 may be useful for characterizing a mixture. As illustrated in callout 1210, which illustrates a close-up view of a portion of dispensing system 1200, as each of components A and B are dispensed, they pass through a sensing system 1220, 1230, respectively. Sensing systems 1220, 1230 each include a PCB sensor, within housing 1222, perpendicular to the flow of material, such that the material flows through a number of slots, each containing an electrode pair that measures a conductivity of the material. Housing 1222 may, in some embodiments, receive a PCB sensor, which can be replaced periodically. PCB sensor is in direct contact with component A 1202.

Sensing system 1220 can be used to verify a material 1202, for example by comparing actual conductivity values to expected conductivity values. For example, values from a previous lot may be compared to currently sensed values to determine quality of a new bath of material. Lot to lot variation may therefore be captured. Additionally, values may be compared from operation to operation to detect aging or other factors that may change how Component A may vary over time. Similarly, sensing system 1230 may be used to verify a material 1204. Sensing systems 1220, 1230 may be connected to a control system which may provide an indication to an operator if sensed conductivity values are outside of an expected range.

A third sensing system 1240 may be present after a mixer, as illustrated in callout 1250, which shows a second enlarged portion of system 1200. Sensing system 1240 has a PCB sensor within a housing 1242. The conductivity sensor includes a plurality of slots perpendicular to the flow of the mixed material. Sensing system 1240 may provide a number of indications, including mixing ratio indications, curing indications, and other information relevant to the quality of mixing. Figures herein illustrate embodiments where sensing systems for incoming components—e.g. 1220, 1230 of FIG. 9A—are separate components. However, it is expressly contemplated that a single sensor could also be used, in some embodiments, that receives both components simultaneously.

As illustrated in FIG. 9B, a housing 1270 may receive material from both parts A and B simultaneously. Because each of the apertures of a PCB-based sensor herein can be decoupled from each other, it is possible to use a single sensor within 1270 to take conductivity measurements from two different materials. In the embodiment illustrated, a first channel 1272 receives a first component and a second channel 1272 receives a second component. While only two component channels are illustrated, it is expressly contemplated that a third channel could receive a third material, etc. Similarly, while two slots are illustrated in each channel of FIG. 9B, it is expressly contemplated that more, or fewer, may be present in other embodiments.

FIG. 9C illustrates a cutaway view of the system of FIG. 9B. As illustrated, channel 1272 receives a Component A and provides it to one or more electrode pairs, through which it flows. Similarly, channel 1274 receives a Component B and provides it to one or more other electrode pairs, on the same PCB sensor. Components A and B flow through housing 1270, with a wall 1276 preventing premature mixing.

FIG. 9D illustrates another system for material characterization. System 1280 provides continuous flow of materials from holding tanks 1284a,b to mixer 1286. Pump system 1282a pumps from a first reservoir while filling the second reservoir. When the first reservoir is empty, a valve flips so that the first side is filled from reservoir 1284a while pump system 1282a pumps material from the second reservoir. Pump system 1282b operates similarly, but drawing from reservoir 1284b. Spikes in conductivity may be detectable anytime a pump 1282a,b changes direction.

System 1280 may have a temperature and/or conductivity sensor at the end of mixer 1286. Continuous flow systems, such as that illustrated in FIG. 9D present advantages because the system is a closed system. However, it may be necessary to purge one or both pump systems. Therefore, it is important to capture the pressure from the output side of a bulk dispenser, which can provide additional context for the information captured by one or more PCB sensors described herein.

In some embodiments herein, a pressure sensor is connected to an exterior of a positive displacement pump. In some embodiments, the pressure signal is captured in amperes. It can be converted to voltage before being provided to an analyzer for analysis. In real-time, in some embodiments, a conductivity, a temperature and a pressure signal can be captured simultaneously.

A fluidic system signal pressure may be measured in amperes, voltage or another suitable unit The ampere measurement may be converted to voltage, for example using a signal NI box converter or another suitable system. The pressure signal can be provided as a digital signal such that it can be analyzed by an analyzer, and used to provide a real-time understanding of pressure in the system. However, it is expressly contemplated that other signal units may be used for analysis, e.g. without converting to voltage. Using current may preserve fidelity of the signal at initial measurement. However, it is expressly contemplated that other methods may be used to retrieve a pressure signal in-situ.

Described herein are a number of sensor configurations that may be used in a variety of dispensers. However, it is also noted that, with sensors herein, a modular dispenser may be used.

FIG. 9E illustrates an example Y-sensor system, which can receive sensors described herein as illustrated at 1292. It is noted that the sensor body 1290 is a single component. This makes it difficult to clean. Additionally, for smaller dispensers, the sensor size is relatively large, taking up a significant surface area of the channel, making flow rates lower. The Y sensor is also difficult to manufacture because of the complex structure.

FIG. 9F illustrates a modular Y-sensor design that is easier to manufacture, as the four components (top, both sensors, bottom) can be manufactured separately, making construction easier. Top portion 1296a receives two components from their source, and provides them through sensors 1296b, before bottom part 1296c delivers components to a mixing chamber. Fasteners 1298 may removably couple components 1296a, 1296b and 1296c together, making them easier to take apart for cleaning.

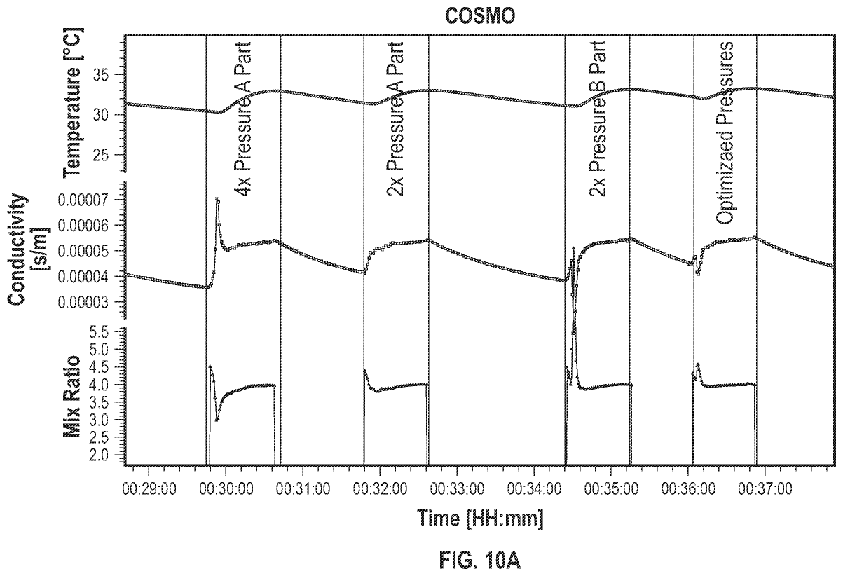

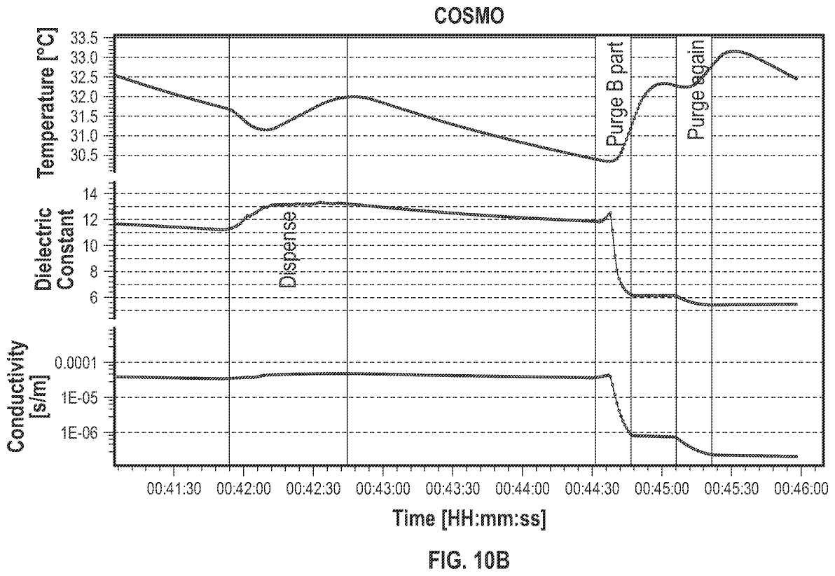

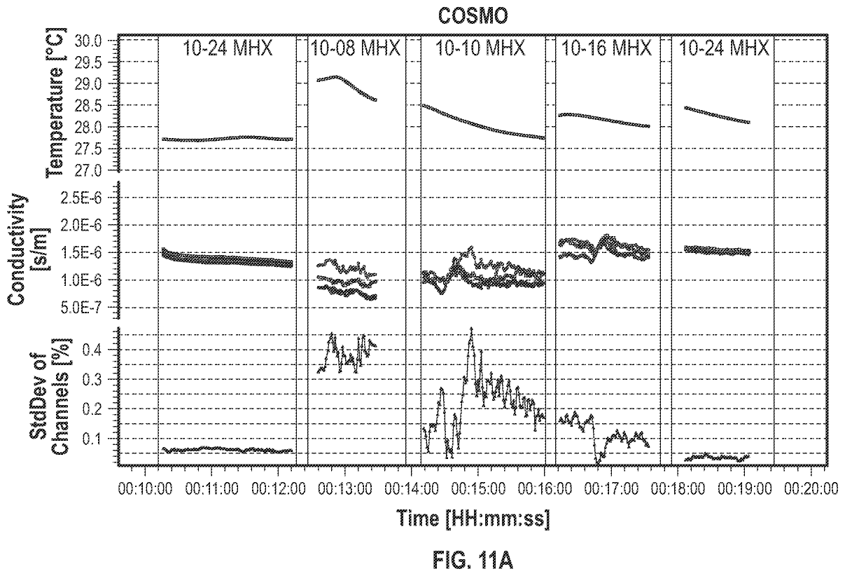

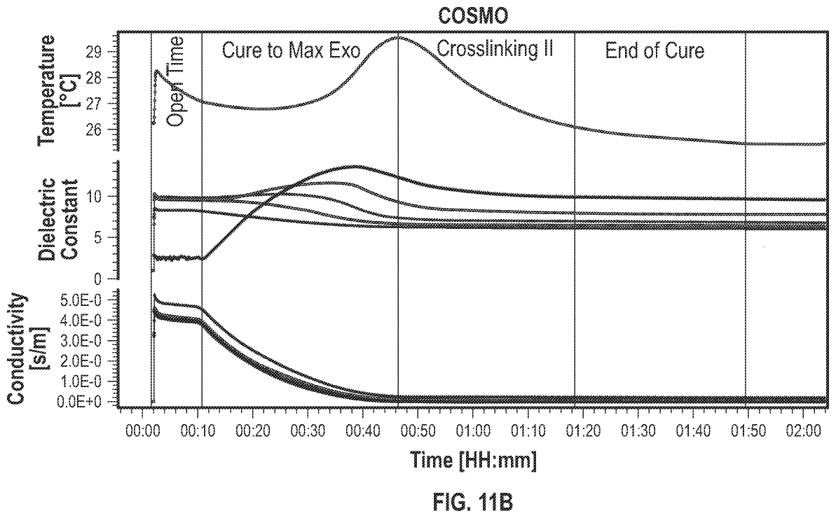

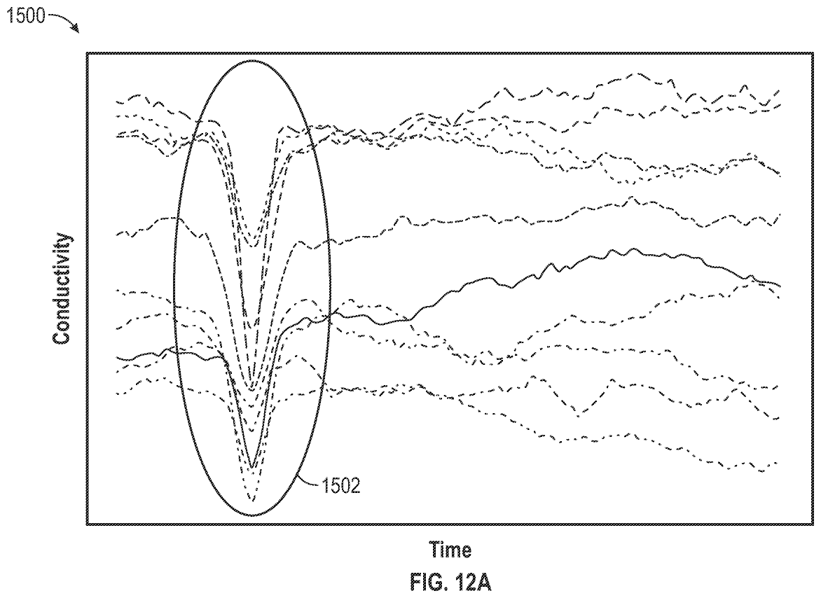

FIGS. 10-11 illustrate example conductivity signals that may be received from embodiments herein. The displays of FIGS. 10-11 may be presented to a user on a display associated with a dispensing system, or on a display remote from a sensing system.

FIGS. 10A-10B illustrate conductivity sensor signals that may be presented during optimization or configuration of a dispensing process. FIG. 10A illustrates a mix ratio, conductivity and temperature measured over time. A series of four dispensing operations are illustrated, with different pressure provided on the A and B components. A first operation is operated at a 4× pressure on component A. A second operation is operated at a 2× pressure on component A. A third operation 1306 is operated at a 2× pressure on component B. The preferred pressure is then set for operation 1308. The preferred pressure is selected to reduce the spike seen in the mixing ratio.

FIG. 10B illustrates conductivity sensor signals that may be presented when a purge is either indicated or automatically initiated. In between dispensing operations, material may sit in a dispenser. In the case of adhesives or other components that experience curing or aging, it may be necessary to purge the system so that the material does not cure and cause system damage. Purge thresholds may be set based on when a material or mixture will have cured either past the point of being useable or past a threshold safe for dispensing machinery. Thresholds may be set by a manufacturer of components, a curing profile, or another source. When a sensed conductivity reaches a threshold after an operation, a purge is initiated. For example, one component may be pushed through a mixer until all of the previously mixed components are flushed through the system. As illustrated, a second purge may be initiated to ensure that the mixture is fully purged, e.g. when a purge threshold is reached.

FIG. 11A illustrates mix quality measurements taken over time. Mixing ratios for each of a two-component mixture are varied for each of five different dispensing operations. The temperature, conductivity, and standard deviation is measured across a set of electrodes in a sensing system. If the standard deviation is above a high threshold, it may indicate that a mixture is not sufficient for dispensing. Below a low threshold, it may indicate that the mixture is sufficient. Between thresholds, a mixing ratio may be adjusted.

FIG. 11B illustrates a measured curing progress for a mixture. One advantage of a disposable sensor system is the ability to use it to measure cure progress. A dielectric constant, conductivity and temperature are measured over time for a number of operational runs. A cure to max exo and an end of cure can be detected using sensor systems described herein, as illustrated. A pot life may be measureable as well.

The GUIs of FIGS. 10-11 can be provided by a smart phone or other user device. The GUIs can also display information regarding the adhesive being dispensed. Example information can include product name, product color, an image of a tube or other container of the product, lot number and other manufacturing information, and expiration date, among other information.

The GUIs of FIGS. 10-11 can display one or more parameters, for example, a desired flow rate of dispensing. In some embodiments, the parameters are user-editable, such that a user can suggest a desired flow rate based on, for example needs of processes downstream of the adhesive process being controlled.

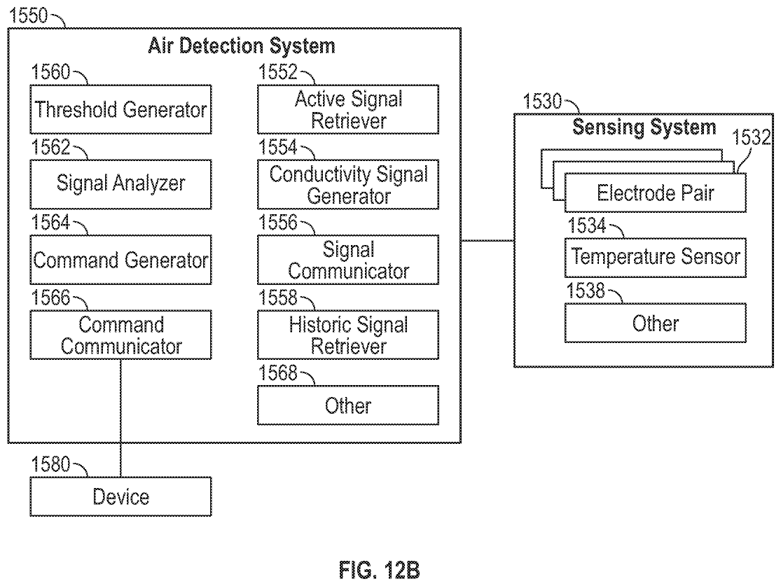

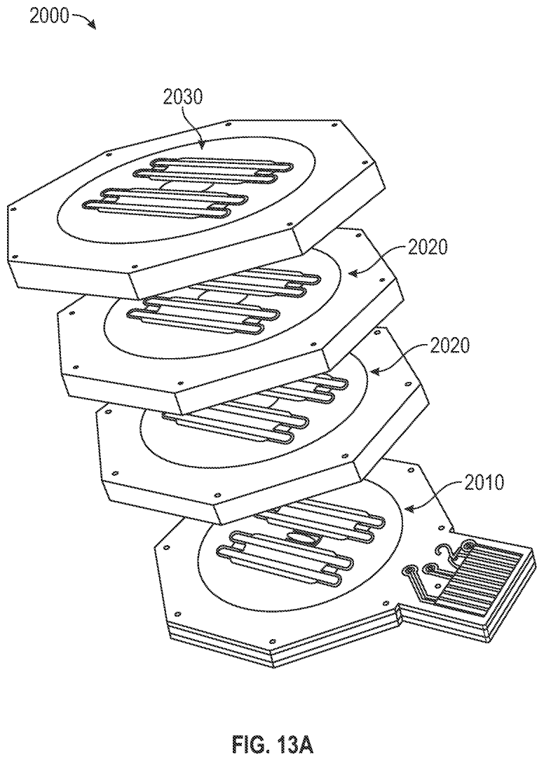

FIGS. 12A-12B illustrates air bubble detection for a material dispensing system in accordance with embodiment herein. FIG. 12A illustrates an example graph of conductivity sensed over time for a number of sensors. As illustrated in chart 1500, by measuring conductivity over time an air bubble can be detected as a spike 1502. The spike may look different depending on raw materials, mixing ratio and the size of the air bubble. For example, as illustrated, a spike may entail conductivity dropping from a first level to a second level, with the amount of drop varying. Additionally, the time frame over which a drop is experience may vary. For example, a larger bubble may take more time to pass through a slot in a PCB sensor and, therefore, may experience a drop over a longer period of time. It is noted that the data presented in chart 1500 is exemplary only, illustrating qualitative air bubble detection, not quantitatively.

Air bubble detection, therefore, may benefit from using relative thresholds instead of absolute thresholds. Base levels may be important to measure to have a more accurate relative threshold. For example, if a conductivity measurement drops below a proportionate factor to the base level (e.g. to 50% of the base level) then an air bubble is detected. Relative thresholds may be helpful to reduce waste of material on accidental purges. FIG. 12B illustrates a system for detecting air bubbles in a material dispensing system. Air detection system 1550 may be implemented by a suitable computing device in communication with a sensing system 1530 associated with a material dispensing system. Sensing system 1530 may include one or more electrode pairs 1532 in direct contact with a material flow. Sensing system 1530 may also include a temperature sensor 1534. Electrode pairs 1532 may be part of a printed circuit board, for example, formed within apertures machined or built into the printed circuit board. The apertures may be closed on both ends, or open on one end, in a comb-like structure, for example. Temperature sensor 1534 may be shielded from direct contact with a material flow, in some embodiments. Sensing system 1532 may include other features 1538.

Sensor signals from sensing system 1530 are received by an air detection system 1550 using an active signal retriever 1552. Active signal retriever 1552 may receive signals from sensing system 1530 periodically or continuously. Received sensor signals may be impedance signals, conductivity signals, dielectric constant signals, or a combination thereof. In embodiments where a conductivity value is used to detect an air bubble, a conductivity signal generator 1554 may convert a received signal to a conductivity value. The signal value, and/or the conductivity value, may be provided to a data store, for example using signal communicator 1556.

A historic signal retriever 1558 may communicate with a data store to retriever previously captured signal values. Historic signal values of interest may include signal values retrieved in a recent period of time, from the same batch or mixture of materials. For example, values retrieved over a previous number of seconds or minutes may be important. As illustrated in chart 1500, signal values may drift over longer periods of time due to changes in temperature, material aging, mixture ratio fluctuations, etc. But a bubble is detectable as a rapid change in conductivity. Threshold generator 1560, in some embodiments, generates a relative threshold either periodically or continuously, based on historic signals. The relative threshold may be an absolute value, for example specifying that an increase or decrease of X % over Y time indicates a bubble. If conductivity values have fluctuated more significantly, the threshold change value may be larger, while if conductivity values have not fluctuated significantly, the threshold change value may be smaller.

Signal analyzer 1562 compares the received signal, or calculated conductivity, to the threshold and, if a deviation outside the allowed threshold is detected, command generator 1564 generates a command, which is communicated, using command communicator 1566, to a device 1580.

Device 1580 may, in some embodiments, include a display component, and the generated command may be an update to a graphical user interface, presented on the display component, indicating the detected air bubble. Device 1580 may, in some embodiments, include a feedback component, such as audio, visual or haptic feedback that indicates to a controller that an air bubble is detected. Device 1580 may also be a valve controller, and command generator 1564 may generate a command to purge the flow line in which the bubble was detected. Device 1580 may also be a motor speed controller, and controller may generate a new motor speed to compensate for the change in mix ratio expected based on the bubble detection.

System 1550 may include other features 1568.

In some embodiments, threshold generator includes a machine learning model to forecast the conductivity time series data into the future from historical data. This forecast may include a so-called confidence intervals. The training may be done upfront on a reference data set without air bubbles. Signal analyzer 1562 then compares a received signal to determine whether it falls within, or outside of, the confidence interval.

In some embodiments, at regular intervals (e.g., 10 ms, 100 ms, etc.), threshold generator generates a prediction for the conductivity value, with confidence bands based on the historic signals retrieved by historic signal retriever. If the actual value measured drops below a lower confidence band, or goes above a higher confidence band, signal analyzer detects a bubble. If the conductivity measurement is within the confidence bands, signal analyzer 1562 provides an output that no bubble has been detected. Command generator 1564 may provide an indication that a GUI of device 1580 does not require updating.

A relative threshold is an important component of an air detection system because of the noise present in the data. The statistical concept of confidence bands can account for this—if data are more noisy, the confidence bands are further away from the current value and the bubble detection algorithm will not yield wrong detections just because of noisy data, where a simple thresholding approach can suffer from this in this case.

While conductivity is discussed herein as the value of interest, it is expressly contemplated that other material parameters, such as the amount of electrical current and the relative permittivity (er), could be used instead or as well for the detections algorithm.

Described herein thus far are sensor systems that are based on a single PCB board. Such systems are relatively inexpensive and, therefore, cost effective to use and replace. However, one disadvantage of designs described thus far is the large stray field compared to the main field present between each electrode pairs. The stray field effect is caused by the short distance between material flow input and output, e.g. the thickness of the PCB. One way to reduce the stray field effect is to solder multiple PCBs, each with electrode-containing apertures, into a PCB stack.

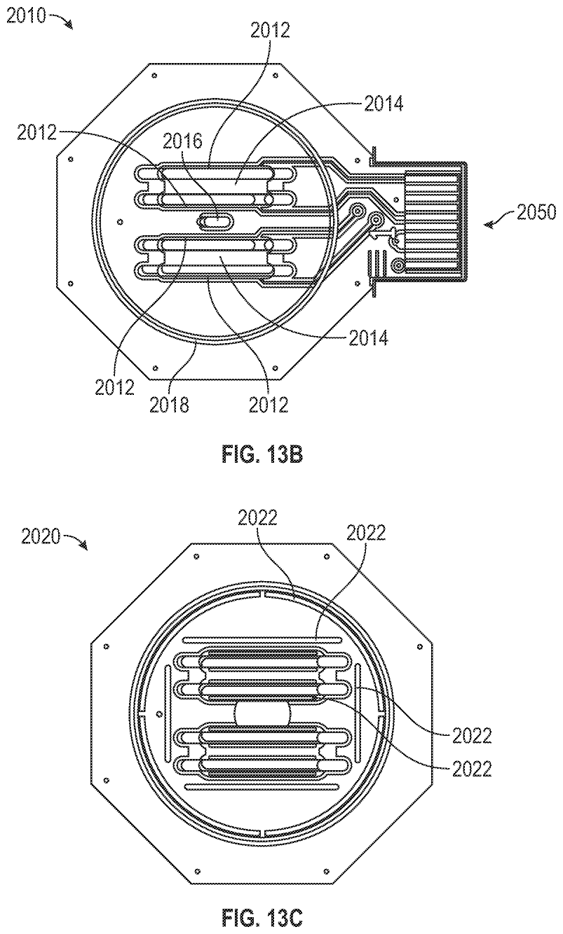

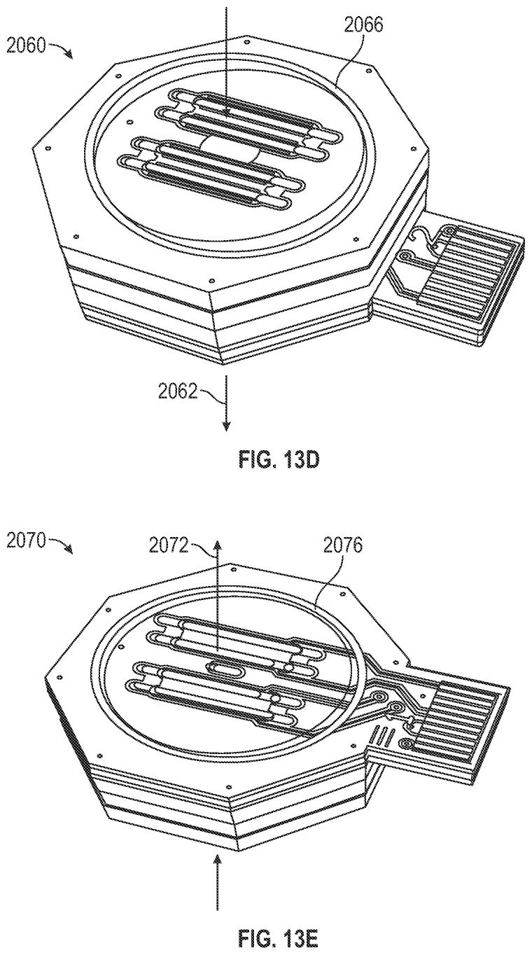

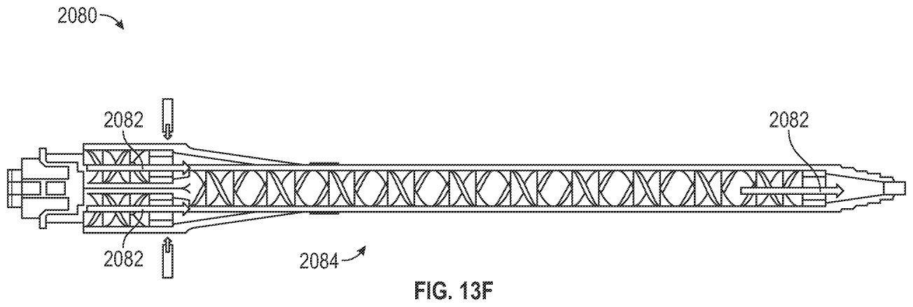

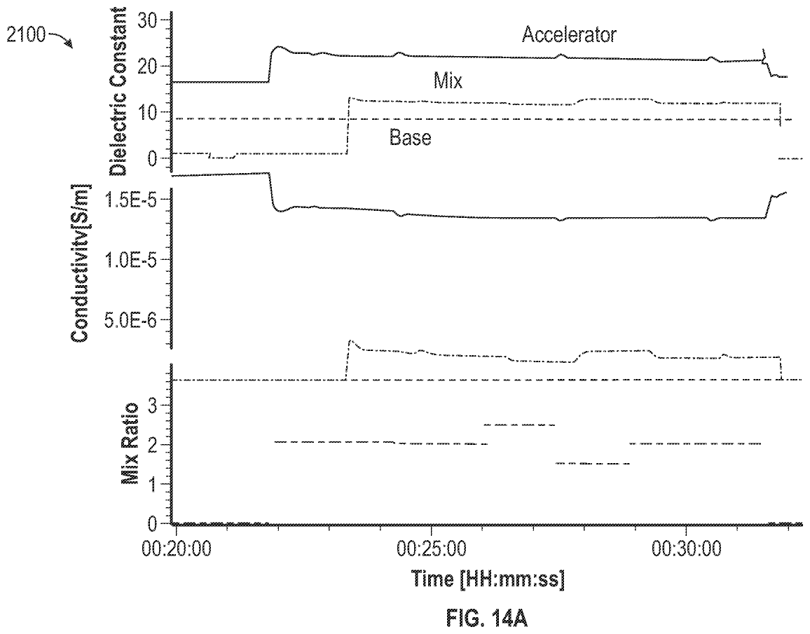

FIGS. 13A-13F illustrate a sensor stack in accordance with an embodiment of the present invention. As illustrated, in one embodiment, sensor stack 2000 may include four PCB sensors, with one 4-layer PCB 2010, two stacking PCBs 2020, which are provided to get the required sensitivity by increasing the electrode surface area, and a top PCB 230. While the embodiment of FIGS. 13A-13F illustrate a four-layer sensor stack, it is expressly contemplated that fewer, or more PCB sensors, may be coupled together. For example, as few as two PCBs or as many as five, six, seven, eight, nine, ten or more PCBs.

Stacked sensor 2000 provides the benefits of a single PCB sensor with reduced stray field effects. The compact design also improves the shielding of the sensitive electrodes, and may also be used as an electrode cartridge without needing additional housing as the sensitive area can be internally sealed. In some embodiments, the sensitive area is internally sealed by soldering, and can withstand applied pressure from a material sensor without requiring an additional housing.

Further, stacked sensor 2000 can utilize smaller electrodes, allowing for sensor stack 2000 to be integrated into an active or passive mixing nozzle at the material inputs as well as the material output.

FIG. 13B illustrates a view of the base sensor 2010. Base sensor 2010 is a four-layer PCB, and includes an edge connector interface 2050. Base sensor includes transmitting electrodes 2014, each paired with a receiving electrode 2012. Sensor 2010 includes a temperature sensor 2016, which is sealed within an aperture of PCB 2010 such that it does not directly contact a fluid flowing through sensor stack 2000. Electrodes 2012, 2014 in contrast, directly contact a fluid as it flows through stack 2000. In embodiments where sensors 2010, 2020 and 2030 are sealed together, sensor 2010 may include a sealing ring space 2018, which may receive solder or another sealing material, such as a sealing ring.

FIG. 13C illustrates an internal PCB sensor 2020. Connection areas 2022 are indicated, which may receive solder or another adhesive. Internal PCB sensors 2020 may be 2-layer PCBs, instead of 4-layer PCBs, which may allow for cost savings, as the additional shielding layers are not necessary for internal sensors 2020. Connection areas 2022 may be soldered, or sealed using another material which allows for communicative coupling between adjacent sensors 2020, 2030, 2010.

FIGS. 13D and 13E illustrate views of a stacked sensor from a material input side 2060 and a material output side 2070. Fluid flows in the direction illustrated by arrows 2062, 2072. A sealing ring 2066, 2076 may be present to seal the PCB sensors to a material flow line. After sealing is complete between all PCB sensors, the sensor stack can be inserted into the material flow by using a sealing ring at sealing points 2066, 2076.

As illustrated in FIGS. 13A-13E, a 4 channel Material-Impedance-Sensor with additional Temperature-Sensor is shown. However, it is expressly contemplated that more, or fewer, channels may be present in some embodiments. Additionally, in some embodiments, no temperature sensor is provided.

FIG. 13F illustrates how a stacked sensor system as illustrated in FIGS. 13A-13E can be utilized in a material dispensing system. A material dispensing system 2080 may have a mixer 2084 with a stacked sensor 2082 at each of a material inlet and a stacked sensor 2082 at the mixer outlet. As described, for example with respect to FIGS. 7 and 9, a material dispenser with a sensing system such as that illustrated in FIG. 13F can allow for improved characterization of the material being dispensed, including detecting batch variations for either input material, verifying mixing ratio, detecting air bubbles, etc. While FIG. 13F illustrates a static mixing system, it is expressly contemplated that embodiments herein would be equally applicable to an active mixer as well.

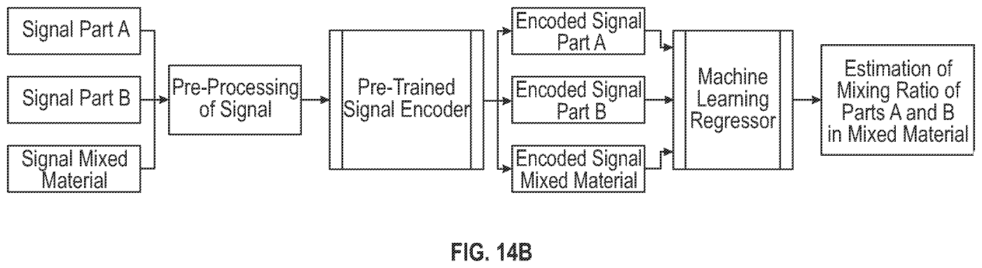

FIGS. 14A-14B illustrate an example batch detail detection for a material dispensing system. As observed in wide exploration of batches, there can be significant variations in conductivities of the A and B parts of a mixture. Therefore, it can be helpful, or even necessary, to conduct calibration measurements each time a new material lot is introduced. It is desired to be able to avoid extensive a-priori characterization of produced materials. By using a system such as that of FIG. 7, 9 or 13F, three signals can be obtained—from each input and the output—and can be fused together to generate one measurement. The input signals and output signal may be corrected for time delay. Each signal has, as illustrated by graph 2100 of FIG. 14A, a conductivity and dielectric constant at various frequencies (e.g. 32 Hz-8 KHz) and a temperature signal at each sensor location. This produces a data vector for each sensor location at a time step. This allows for extraction of mixing ratios at varying operating conductions as a dispensing operation proceeds.

FIG. 14B illustrates an example model for estimating mixing ratio based on received signals from each of a Part A component, a Part B component and a Mixture. In some embodiments, the signal encoder is a pre-trained generative model, e. g. a Variational Autoencoder (VAE), that is trained to encode all signals into a representation and to decode the original signal from this representation. However other models may also be suitable. A VAE may ensure that the representation of the signal includes all information that is needed to reconstruct it. The encoder takes one signal as an input and outputs the representation in the latent space of that signal. The decoder takes one representation as an input and outputs the reconstructed signal.

The machine learning model that estimates the mixing ratio of part A and part B in the mixed material then takes the three pre-processed and encoded signals from part A, part B and the mixed material as inputs and outputs the mixing ratio in the mixed material.

Signal encoder and regressor may operate locally, for example using a computer processing device associated with a material dispensing system. Alternatively, either encoder or regressor, or both, may be deployed in a cloud-based storage system.

The output of encoder may be directly used to apply pressure changes on the cartridges associated with components A and B to ensure that the mixture meets a predefined mixing ratio. E.g., if the mixed material contains too much of part A, the pressure on the cartridge containing part A is reduced and the pressure on the cartridge that contains part B increased.

A regressor may then take the encoded signals and produce a mixing ratio signal. The regressor may be a machine learning based algorithm that can be trained in any suitable way.

A first training option is a separate training option where the Encoder-Decoder model is trained on a set of signals of a variety of parts for part A, part B, and diverse mixtures. The Machine Learning Regressor is trained in a second step afterwards on the encoded signals and the corresponding mixing ratios.

A second training option is an alternating training option, where one batch of signals is used for one training step in the Encoder-Decoder and then used for one training step in the Encoder-Machine Learning Regressor part. A training step consists of a forward pass of the data in a batch, the calculation of the gradient, and an application of the gradient to optimize the weights in the model.

A third training option is a combined training option where the triplet of Encoder-Decoder pair and Machine Learning model are optimized simultaneously. This means that a batch is forward through the Encoder, and the representation obtained is forwarded through the Decoder and the Machine Learning Regressor. Then the gradients calculated with both outputs are applied in a weighted combination in the backwards pass.

Alternating or combined training may provide a benefit in that the representation of the signals is learned in a way that it has a positive effect on the performance of the Regressor which can lead to a lower error when estimating the mixing ratio. Learning a representation of signals on a variety of materials and mixing ratios also allows the models to be used on previously unseen materials of the same chemical family.

In difference to a system which only uses a single signal from the mixed material, this novel approach allows adaption for lot-to-lot variation of the raw material, where a change in one of the parts can lead to a change in the mixed signal for the same mixing ratio. It also enables tracking the mixing ratio of the new materials of the same family be learning to fuse the signals of two parts into a mixed signal. Additionally, data traces collected from a sensor system can be processed to provide other information than just a mixing ratio. As described herein, in some embodiments, a sensor includes four electrode pairs. A time series of conductivity can be analyzed from the four sensor capacitors:

$$\begin{matrix}{σ}_{i} ( t ) , & i ∈ \{ 1 , 2 , 3 , 4 \}\end{matrix} \qquad Equation l$$

Incomplete mixing, for example from using a static mixer that is too short, appears in the sensor output as high volatility. The volatility can be quantified by calculating the variance over a time window, e.g. 10 seconds. The time window may vary based on the speed of the process and mixer throughput.

$${V}_{i}^{10 s} ( t ) = \frac{1}{10 s} {\int }_{t - 10 s}^{t} {{σ}_{i} ( τ )}^{2} - {\overline{{σ}_{ι}} ( τ , 10 s )}^{2} d τ \qquad Equation 2$$

With

$$\overline{{σ}_{ι}} ( t , Δ t ) = {\int }_{t - Δ t}^{t} {σ}_{i} ( τ ) d τ \qquad Equation 3$$

If the mixer is adequate, the variance of each sensor, once flow is stable, will drop below a threshold that can be determined experimentally.

Mixing may also take time to reach a steady state. For example, when starting a mixing operation, backpressure and different viscosities of components can cause mixing to start off poorly and gradually stabilize. The same variance can be used to track the stabilization and indicate when the dispenser can dispense material on a workpiece or to a receiving container. The trend of the variance can be analyzed using Equation 4.

$${V}_{i} ( t ) - {V}_{i} ( t - Δ t ) < {V}_{thresh} \qquad Equation 4$$

The threshold Vₜₕᵣₑₛₕ is specific for each material. Instead of determining a threshold, the signal can be tested for stationarity using the augmented Dickey-Fuller test. The advantage with this is that manual thresholds often need to be tuned for a new batch, but the ADF test is adaptable.

Inhomogeneity can also be detected using sensors described herein. The four electrode pairs should also record similar readings. Some constant offset is possible due to manufacturing tolerances, but in a stable mixing process, the variations of the four signals should be synchronous. To check for this, calculate the covariance of the signals without time shift:

$${C}_{i , j}^{Δ t} ( t ) = {\int }_{t - Δ t}^{t} ( {σ}_{i} ( τ ) - \overline{{σ}_{ι}} ( τ , Δ t ) ) \cdot ( {σ}_{j} ( τ ) - {\overline{σ}}_{j} ( τ , Δ t ) ) d τ \qquad Equation 5$$

Once each signal has stabilized, the four sensors should have a high covariance. Negative covariance indicates a persisting anti-correlated behavior and signifies spatial inhomogeneity.

Similarly, a single component of the 2K adhesive can also be inhomogeneous, e.g., because of settling in the barrel or insufficient mixing during manufacturing. An augmented Dickey-Fuller test can again be used to confirm stationarity over a longer time. The relevant time frame would be determined by the time it takes to empty the container.

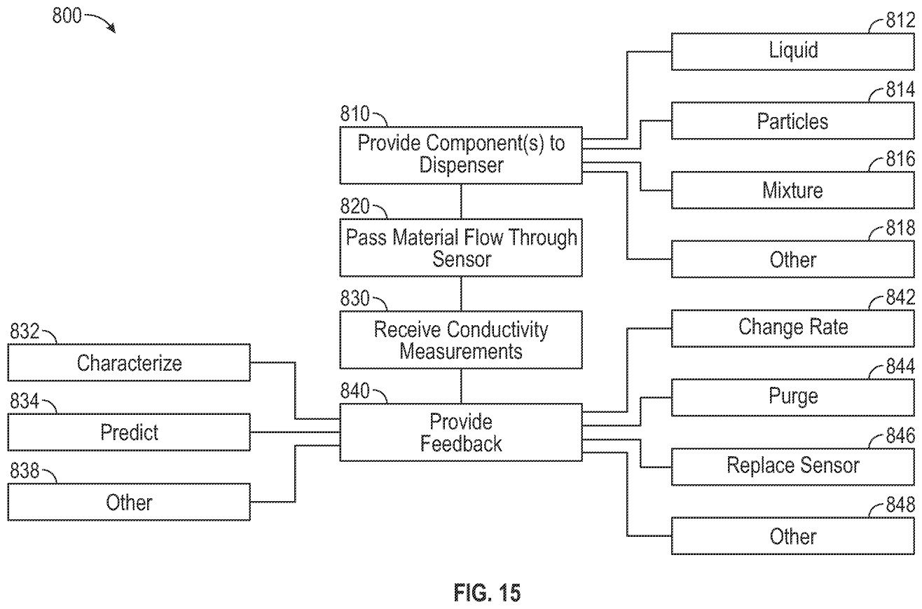

FIG. 15 illustrates a method of controlling a material dispensing system in accordance with embodiments herein. Method 700 may be used with the dispensers described herein, or another suitable sensing system.

In block 810, one or more components to be dispensed are provided to a dispenser. For example, a dispenser may dispense a liquid 812, particles 814 either in suspension or otherwise. The material may also be a mixture 816 of materials. For example, an adhesive may be formed of an A and B component provided at a desired mix ratio. Other components 818 may also be provided to a dispenser for dispensing.

In block 820, the material passes through a sensing system before being dispensed onto a worksurface. Passing through a sensing system may entail passing through a portion of a sensing body such that the material directly contacts a sensor. For conductivity sensors, direct contact between a material and an electrode pair ensures accurate measurements.

In block 830, conductivity measurements are received from the sensing system. The sensing system may have multiple sensors, for example a plurality of electrode pairs that, when a sufficient voltage is passed through them, detects a conductivity of the material. Based on the conductivity readings, a number of things may be determined for the material. For a mixture, a mixing ratio may be determined. For a curable material, a curing progressing may be detected. Aging may also be detectable, as well as differences between batches of materials. Entrained air may also be detectable. Conductivity measurements may be taken serially, for example one signal received every second, or more frequently. Conductivity measurements may also be taken in parallel, for example from each of a plurality of electrode pairs. The electrode pairs may be coplanar with each other, in some embodiments.

In block 840, feedback is provided based on the conductivity measurements. Feedback may include characterization of the material, as indicated in block 832. For example, a mix ratio may be detected, or entrained air, or an age indication may be provided. A prediction may also be provided, as indicated in block 834. For example, based on a trend of previous conductivity sensor readings, it may be possible to predict future behavior. A conductivity reading trending in one direction may indicate that a mix ratio is moving toward an edge of an acceptable range and, therefore, that a mix rate should be changed, as indicated in block 842. Similarly, a conductivity reading may indicate that a curable component is curing. Feedback may therefore indicate that a purge of one component, multiple components, or a mixture, is needed, as indicated in block 844. In embodiments where a material has corrosive effects, or cures over time, predictive feedback may provide an indication that the sensor needs to be replaced, as indicated in block 846. Other predictive information may also be provided, as indicated in block 838, that may trigger other actions, as indicated in block 848.

In some embodiments, as illustrated herein, providing feedback may also include providing conductivity readings, material characterizations or predictions to a customer, controller of a dispenser, or other useful information such as material source, batch number, material name, dispensing temperature, dispensing pressure, material concentration(s), mix ratio, or any other information.

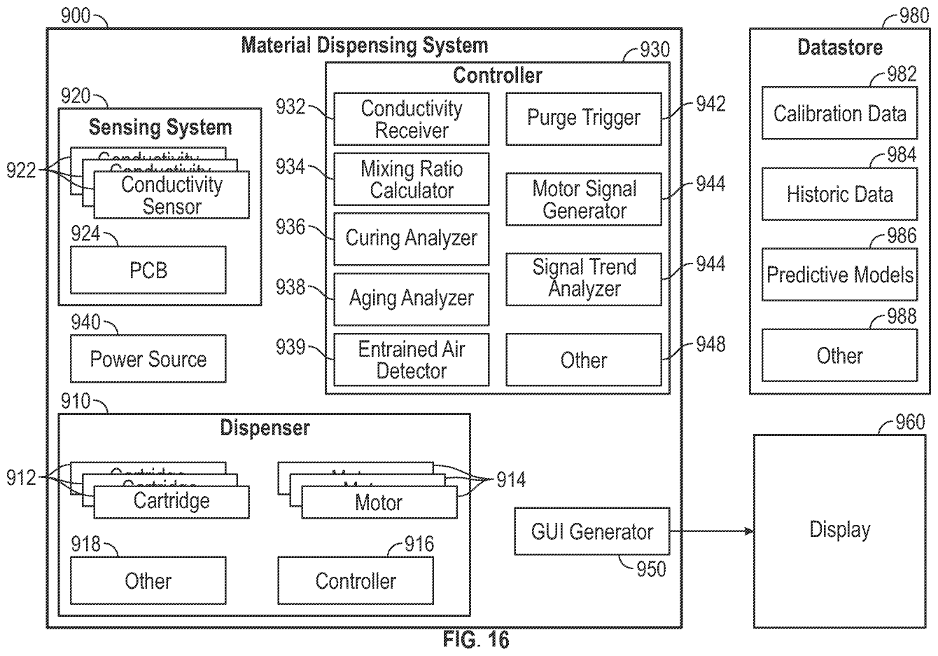

FIG. 16 illustrates a material dispensing system in accordance with embodiments herein. System 900 may include a dispenser 910 with one or more cartridges 912 containing a material to be dispensed. A cartridge 912 may dispense material at a rate based in part on a speed of a corresponding motor 914. A dispenser controller 916 may provide a control signal to motor(s) 914 to drive material flow from each cartridge 912 by increasing or decreasing a speed of corresponding motors 914. Dispenser 910 may have other features 918, such as a heating or cooling element if material is dispensed at an elevated temperature or if heat needs to be provided or removed from an exothermic or endothermic reaction of reactive components.

Dispensing system 900 may also include a sensing system 920, with one or more conductivity sensors 922 arranged on a PCB board 924. The PCB board 924 may include one or more ground planes, one or more contact points to connect to a system controller 930 or to power source 940, or another source. Sensors 922 may be coplanar on PCB 924, for example formed within slots of PCB 924, either by metallization or another process. Sensors 922 may be decoupled from each other such that independent conductivity signals are received from each sensor. Sensors 922 may each comprise a positive and negative electrode, decoupled from one another.

A controller 930 may receive sensor signals from sensing system 920, using signal receiver 932. Signals may be received as a conductivity signal or a dielectric constant signal, but may also be received as an impedance signal. In embodiments where a received signal is an impedance signal, a conductivity calculator 933 may calculate a conductivity value based on the impedance signal. Similarly, a dielectric constant calculator 935 may calculate a dielectric constant value based on the impedance signal. Based on received sensor signals, controller 930 may trigger a number of calculations and/or predictions. For example, a mixing analyzer 934 may calculate a mixing ratio of a mixture of components being dispensed. A mixing ratio 934 may be calculated based on calibration data 982, stored in a datastore 980, which may be indicative of conductivity data from pure components and/or known mixtures of components. As described above, sensors may be placed at both the inlets and outlet of a mixer and, therefore, mixing analyzer 934 may receive sensor signals from all sensors associated with a material dispensing system. Mixing analyzer 934 may correct for the time delay between the sensors.

A curing analyzer 936 may also, based on the conductivity signals, detect that curing is occurring and a progression of the curing. For example, if curing progresses significantly, then a purge trigger 942 may need to trigger a purge of one or more components, or of a mixture of components. Similarly, an indication may be provided that PCB 924 should be replaced based on curing that could damage or render sensor 922 inaccurate. Based on a comparison of contemporaneous conductivity signals against calibration data 982, or historic data from system 900 or another system, aging analyzer 938 may detect an age of one or more components, or a mixture, and provide an indication as to whether the material should be discarded. It may also be possible, based on conductivity sensor signals, to detect entrained air using an entrained air detector 939. These, and other parameters 948, may also be detectable.

Controller 930 may also be able to, using historic data 984 from a current dispensing operation or historic dispensing operations, analyze a trend using signal trend analyzer 944 Curing may begin anytime that dispensing is not occurring and material sits within the dispenser, e.g. in between flowing cycles. Similarly, it is possible to detect that a purge can end, e.g. if conductivity is below about 6 or about 5.5, purging may be finished. Curing progress may also be explicitly tracked to verify that the cure progresses in line with expectations. Curing may have some volume dependency, but sensor system 920 may provide an indication that a material meets specifications based on a curing profile.

Controller 930 may also be able to, based on sensor signals, use a composition drift analyzer 937 to detect a change in composition over time. Controller 930 may also be able to, using homogeneity analyzer 943, determine whether input material is homogeneous when entering the mixer.

At start up, controller 930 may cause start up analyzer 941 to monitor incoming material streams and the mixer output to determine when the mixing process has stabilized.

Controller 930 may also be in communicable contact with other devices, such that a command generator 942 can generate a device command, and command communicator 944 to communicate the device command. For example, if mixing analyzer 934 detects that a mixing ratio is off, a motor signal may be generated, by command generator, to adjust a speed of a motor 914 before a mixing ratio exceeds or drops below an acceptable threshold. Similarly, a purge of a cartridge 912 maybe triggered or ended by command generator 942, based on detected curing or aging of material using curing analyzer 936. For example, it may be known, for a given material, that if conductivity increases by another X %, that the material will no longer be dispensable, and a purge may be triggered.

Other information 988 may be stored in datastore 980 and accessible by controller 930 for analysis and improved operation of dispenser 910 or sensing system 920. For example, material information 987 may be stored in datastore 980. Datastore 980 may be local to controller 930, or may be accessible through a cloud-based network. Similarly, while controller 930 is illustrated in FIG. 16 as local to dispensing system 930, it is expressly contemplated that controller 930 may be remote from material dispensing system and may receive signals, and send commands, using a wireless or cloud-based network.

A GUI generator 950 may generate a graphical user interface for display on a display component 960 based on some or all of the information gathered or generated by controller 930. For example, conductivity sensor data may be presented. A calculated mixing ratio may also be presented, as well as dispensing parameters, including target mixing ratio, motor speed, pressure, temperature, etc.

Another component that a dispenser 910 may have is a mixing element with one or more mixing elements. It is desired to have the minimum possible mixing elements to reduce complexity of dispenser 910, and associated cost. Similarly, the more internal surface area within the dispenser, the more material must be wasted or purged at the end of an operation time. Mixing may be considered sufficient, in some embodiments, if the standard deviation between a number of coplanar conductivity sensors is below 0.1. If a conductivity of a material varies by more than that across a sensing plane, then the mixing element may need to be elongated. For a new adhesive or mixture, sensing systems herein may be useful for designing a suitable static mixer. For active mixers, sensors herein may be useful for sensing and adjusting a rotation speech until a material mixture is satisfactory.

Systems and methods are described herein that take advantage of machine learning algorithms. Machine learning models may be preferred because they can better handle noisy data, make predictions about future signal trends, and make adjustments before mix quality significantly shifts. Systems and methods described herein can calculate the mix ratio real time. With machine learning techniques, the mix ratio could be predicted ahead of time. This allows quicker adjustments which keeps the mix ratio closer to the target value more of the time. With some current dispensers, a lot of material is entrained in the static mixer, such that, by the time a shift in mix ratio is detected, the material already in the mixer will continue to have the wrong mix ratio for at least a mixer's worth of adhesive, so identifying mix ratio issues earlier can save material and a potential purge.

Similarly, machine learning models, as described herein, may receive information from multiple systems, such as multiple sensors within a dispensing system including conductivity sensors, temperature sensors, motor speed signals, material information, etc. In some embodiment, multiple machine learning models are used simultaneously, each by an individual system such that each system's model can learn and the overall model can be improved. However, it is also expressly contemplated that non-machine learning models may also be used.

Controller 930 is described as having the functionality of receiving and sending communicable information to and from other devices. This may be done through an application program interface, for example, such that controller 930 can receive and communicate with pump controllers, line pressure sensors, movement controllers for portions of dispensing system, temperature sensors, heating elements, datastores having information for any of the materials being dispensed or the mixture being generated, etc.

In embodiments where machine learning models are used, datastore may also include an analyzer that learns usage behavior of a particular dispensing system in order to improve operation and predictions. Similarly, frequency and patterns of dispensing may provide information about curing and improve mixing models. For example, usage data such as frequency of dispense, purging frequency, pattern of dispense, change out of the sensor, etc, can be collected and used to enable a model to learn about adhesive curing. This additional data can be included in the adhesive characterization and improve the predictive power of models build on the sensor data. Curing is dependent on many factors including length, width, and other geometry of the static mixer, the exothermic properties of the adhesive, the reaction kinetics, downstream attachments such as tubes or tips, time, and other factors. It is not enough to only know about the reaction kinetics of the adhesive itself. With this amount of complexity, collecting the usage data and training a machine learning model is the best way to enable higher quality predictions which in turn enables higher quality feedback and control over the process.

In embodiments where inventory information is also stored in a datastore 980, or otherwise accessible by controller 930, controller 930 may indicate that inventory is low or order material based on low inventory.

Similarly, as described herein, display 960 may display a GUI created by generator 950 that is updated periodically with information that controller 930 has access to, such as any sensor data received, any analysis results generated by analyzers 934, 936, 938, 939, 937, 941, 943, any information retrieved from datastore 980, etc. Information may be passively updated, or provided with an alert or notification as it is updated, for example current status information may be presented and an alert (visual, audio, or haptic) may be provided if the mixing ratio is drifting toward an unacceptable range. Additionally, or alternatively, notifications may be provided when a device command is generated, or when operator intervention is needed. For example, in embodiments where command generator 942 is not able to communicate with another device, command communicator 944 may send a message to display 960, or to a speaker, or another notification device, to indicate to the operator that a purge is needed, that a motor speed needs to be changed, that the temperature is too high or low, etc.

In some embodiments herein, it is envisioned that controller 930 may generate commands, using command generator 942, to maintain a mixture output within desired parameter ranges, such as purging a detected bubble, adjusting motor speeds to maintain mixing ratio, increasing or decreasing heating elements to maintain desired viscosity, etc. Fine tuning may be provided automatically. However, there are situations where controller 930 may not be able to use fine tuning to maintain a desired mixture output—such as the presence of bubbles, line blockages or material running out. Controller 930 may be able to address bubbles as described herein. Controller 930 may also be able to detect blockages or low material based on historic behavior of dispensing system 900. In situations where controller 930 cannot maintain desired mixture parameters, it may trigger an alarm, notification, or otherwise indicate that the mixture provided is not on-spec.

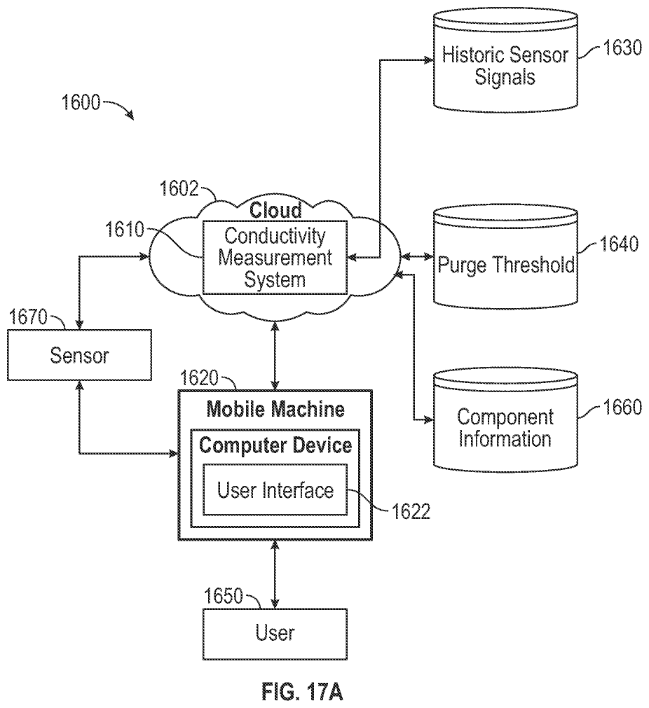

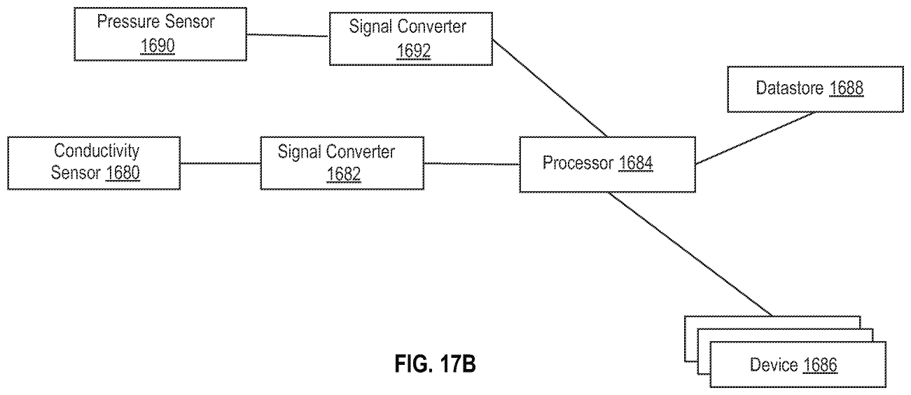

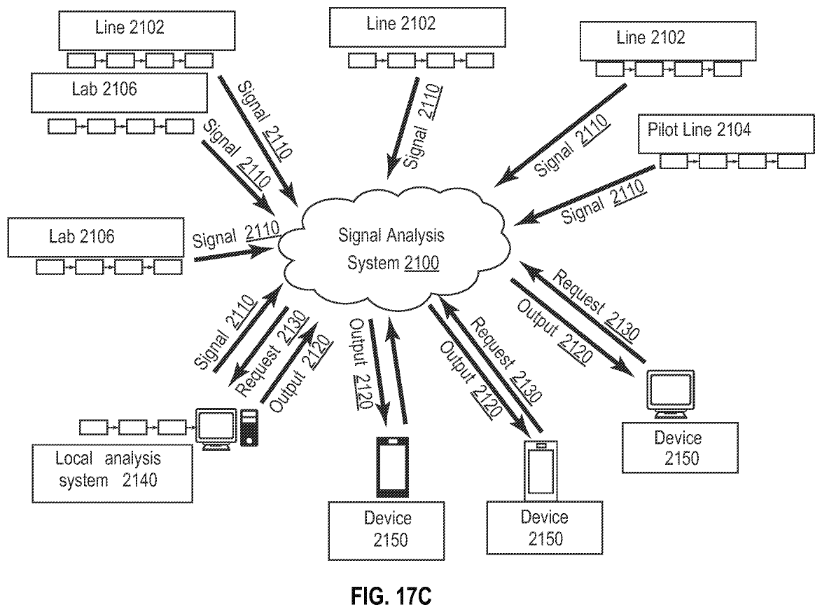

FIG. 17A illustrates a concentration profile simulation system architecture. Architecture 1600 illustrates one embodiment of an implementation of a conductivity sensing system 1610. As an example, architecture 1600 can provide computation, software, data access, and storage services that do not require end-user knowledge of the physical location or configuration of the system that delivers the services. In various embodiments, remote servers can deliver the services over a wide area network, such as the internet, using appropriate protocols. For instance, remote servers can deliver applications over a wide area network and they can be accessed through a web browser or any other computing component. Software or components shown or described in FIGS. 1-16 as well as the corresponding data, can be stored on servers at a remote location. The computing resources in a remote server environment can be consolidated at a remote data center location or they can be dispersed. Remote server infrastructures can deliver services through shared data centers, even though they appear as a single point of access for the user. Thus, the components and functions described herein can be provided from a remote server at a remote location using a remote server architecture. Alternatively, they can be provided by a conventional server, installed on client devices directly, or in other ways.

In the example shown in FIG. 17, some items are similar to those shown in earlier figures. FIG. 17 specifically shows that a conductivity sensing system 1610 can be located at a remote server location 1602. Therefore, computing device 1620 accesses those systems through remote server location 1602. User 1650 can use computing device 1620 to access user interfaces 1622 as well. For example, a user 1650 may be a user wanting to check a fit of their respiratory protection device while sitting in a parking lot, and interacting with an application on the user interface 1622 of their smartphone 1620, or laptop 1620, or other computing device 1620.

FIG. 17 shows that it is also contemplated that some elements of systems described herein are disposed at remote server location 1602 while others are not. By way of example, data stores 1630, 1640 and/or 1660 can be disposed at a location separate from location 1602 and accessed through the remote server at location 1602. Regardless of where they are located, they can be accessed directly by computing device 1620, through a network (either a wide area network or a local area network), hosted at a remote site by a service, provided as a service, or accessed by a connection service that resides in a remote location. Also, the data can be stored in substantially any location and intermittently accessed by, or forwarded to, interested parties. For instance, physical carriers can be used instead of, or in addition to, electromagnetic wave carriers. This may allow a user 1650 to interact with system 1610 through their computing device 1660, to initiate a seal check process.

It will also be noted that the elements of systems described herein, or portions of them, can be disposed on a wide variety of different devices. Some of those devices include servers, desktop computers, laptop computers, imbedded computer, industrial controllers, tablet computers, or other mobile devices, such as palm top computers, cell phones, smart phones, multimedia players, personal digital assistants, etc.

FIG. 17B illustrates an example system architecture. In the embodiment of FIG. 17B, the system is connected through wires, such that it is not a wireless or open distributing solution. Wired communication may also be preferred in embodiments where a wireless connection would have slower transfer rates or potentially unreliability. However, as discussed with respect to FIG. 17A, it is contemplated that wireless systems may also be possible.

A conductivity sensor 1680 may capture a conductivity signal, for example from one or more PCB sensors described herein, provide that sensor signal to a signal converter 1682 where, if needed, signal conversion occurs. However, it is expressly contemplated that in some embodiments conductivity sensor 1680 may provide a sensor signal directly to processor 1684. Signal converter 1682 may convert, for example, impedance to conductivity, an analog to a digital signal, or may do another suitable conversion.

Processor 1684 receives a conductivity indication, and generates a conductivity output, which may be provided to one or more devices 1686. Devices 1686 may include a computing device with display, a smart phone with display, a laptop with display, or to another device, for example a storage medium which stores the conductivity sensor signal for future reference. Processor 1684 may also consult one or more data stores 1688 in order to generate additional indications. For example, data store 1688 may include past conductivity sensor signals, conductivity sensor signal thresholds, commands to adjust dispensing parameters based on conductivity signal thresholds, etc. Processor 1684 may act accordingly.

In accordance with embodiments herein, system may also have a pressure sensor 1690 that generates a pressure signal, indicative of a detected pressure at a point within the dispensing system. If needed, a signal converter 1692 may convert the pressure signal from one form to another, from ampere to voltage, analog-to-digital, etc.

Processor 1684, or another suitable processor, may generate a pressure output, which may be provided to one or more devices 1686. Processor 1684 may receive signals from pressure sensor 1690 and conductivity sensor 1680 continuously throughout a process, and may be able to generate outputs continuously as well, providing substantially real time information about a dispensing system. Processor 1684 may include one or more suitable machine learning techniques, may consult a lookup table, or perform another suitable data analysis technique on a received conductivity signal or pressure signal.

Processor 1684 may communicate with sensors 1680, 1690 wirelessly, using a wired connection, or through any other suitable network. Processor 1684 may receive signals as encrypted signals, may provide output as an encrypted output, or may operate without encryption protocols in place.

In some embodiments, a data broker (such as an MQTT broker) is used such that receiving devices or sending devices can control what data is sent. For example, a site manager may be in charge of lines 1-3 and, therefore, does not need to receive data from lines 4-6. Site manager may want to review only status information (e.g. mix ratio drift detected) and is not interested in a graphical user interface that displays current flow measurements graphically.

In some embodiments, processor 1684 also communicates with data store 1688, such that conductivity and pressure signals are also stored for later analysis. For example, a data set including conductivity and pressure signals over time may be used to train a machine learning algorithm, or may be used for troubleshooting purposes. For example, a machine learning algorithm may be able to detect patterns in the data set, such as an off mix ratio and need to purge, and provide indications and or thresholds about how to detect when mix ratio deviation occurs before the deviation become severe.

FIG. 17B illustrates a single processor that receives information from a single set of sensors for a dispensing operation. However, it is expressly contemplated that a production environment may have multiple dispensers running with multiple conductivity sensors and pressure sensors providing status information continuously. It is anticipated, therefore, that multiple users may want to view information about multiple production lines at the same time. FIG. 17C illustrates one configuration of a system that may be able to provide such functionality.

FIG. 17C illustrates a signal analysis system 2100 that communicates with a number of devices using a cloud-based network. —As illustrated in FIG. 7C signal analysis system 2100 may communicate with a local analysis system 2140, such as that described with respect to FIG. 17B. Signal analysis system 2100 may receive a number of sensor signal data 2110 from a number of dispensing operations, such as a pilot line 2104, any of an operational line 2102, and/or a laboratory set up 2106. As described with respect to FIG. 17B, sensor signals 2100 may be digital signals, analog signals, conductivity measurement signals, pressure signals, or other signal information. —For example, a low reservoir detected signal, a valve switch indication, or any other detectable indication from any of systems 2102-2106.

Signal analysis system 2100 may conduct analysis on receive sensor signal information 2100, for example using any suitable analysis tool such as lookup table, comparison thresholds, and/or machine learning algorithms to detect parameter trend information that may indicate a problem, or an action that needs to be taken, such as purging, adjusting mix ratio, etc.

Signal analysis of 2100 may provide output indicia 2120 a number of suitable devices 2150. Signal analysis system 2100 may provide output information 2120 continuously, or in response to a request 2130 information. Or request 2130 may be a one-time request for current status information, or a request to receive continuous updates going forward.

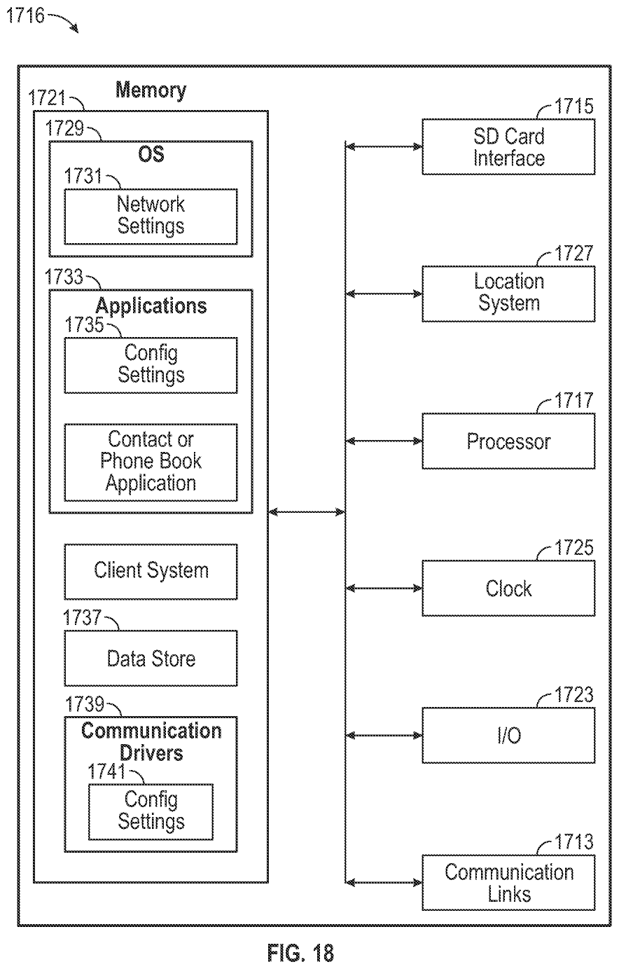

FIGS. 18-20 illustrate example devices that can be used in the embodiments shown in previous Figures. FIG. 18 illustrates an example mobile device that can be used in the embodiments shown in previous Figures. FIG. 18 is a simplified block diagram of one illustrative example of a handheld or mobile computing device that can be used as either a worker's device or a supervisor/safety officer device, for example, in which the present system (or parts of it) can be deployed. For instance, a mobile device can be deployed in the operator compartment of computing device for use in generating, processing, or displaying the data.

FIG. 18 provides a general block diagram of the components of a mobile cellular device 1716 that can run some components shown and described herein. Mobile cellular device 1716 interacts with them or runs some and interacts with some. In the device 1716, a communications link 1713 is provided that allows the handheld device to communicate with other computing devices and under some embodiments provides a channel for receiving information automatically, such as by scanning. Examples of communications link 1713 include allowing communication though one or more communication protocols, such as wireless services used to provide cellular access to a network, as well as protocols that provide local wireless connections to networks.

In other examples, applications can be received on a removable Secure Digital (SD) card that is connected to an interface 1715. Interface 1715 and communication links 1713 communicate with a processor 1717 (which can also embody a processor) along a bus that is also connected to memory 1721 and input/output (I/O) components 1723, as well as clock 1725 and location system 1727.

I/O components 1723, in one embodiment, are provided to facilitate input and output operations and the device 1716 can include input components such as buttons, touch sensors, optical sensors, microphones, touch screens, proximity sensors, accelerometers, orientation sensors and output components such as a display device, a speaker, and or a printer port. Other I/O components 1723 can be used as well.

Clock 1725 illustratively comprises a real time clock component that outputs a time and ate. It can also provide timing functions for processor 1717.

Illustratively, location system 1727 includes a component that outputs a current geographical location of device 1716. This can include, for instance, a global positioning system (GPS) receiver, a LORAN system, a dead reckoning system, a cellular triangulation system, or other positioning system. It can also include, for example, mapping software or navigation software that generates desired maps, navigation routes and other geographic functions.

Memory 1721 stores operating system 1729, network settings 1731, applications 1733, application configuration settings 1735, data store 1737, communication drivers 1739, and communication configuration settings 1741. Memory 1721 can include all types of tangible volatile and non-volatile computer-readable memory devices. It can also include computer storage media (described below). Memory 1721 stores computer readable instructions that, when executed by processor 1717, cause the processor to perform computer-implemented steps or functions according to the instructions. Processor 1717 can be activated by other components to facilitate their functionality as well. It is expressly contemplated that, while a physical memory store 1721 is illustrated as part of a device, that cloud computing options, where some data and/or processing is done using a remote service, are available.

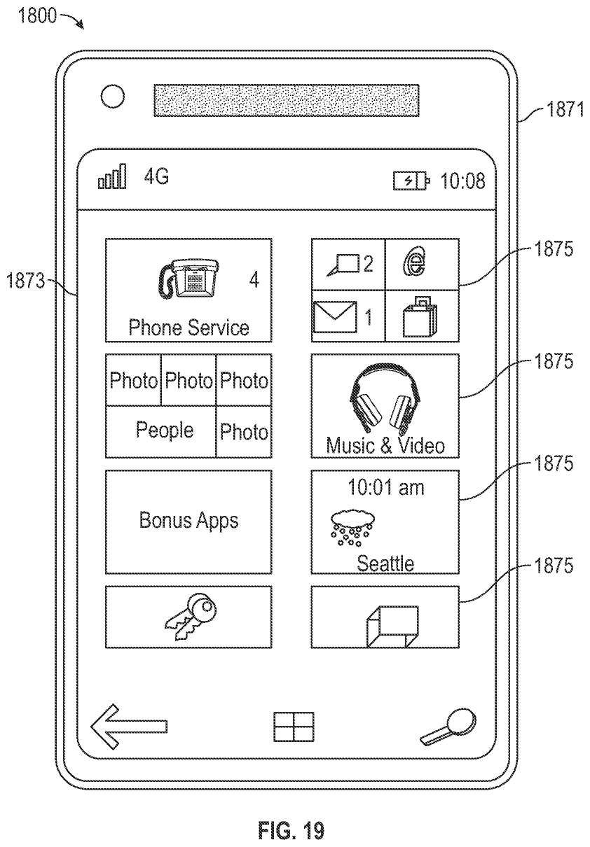

FIG. 19 shows that the device can also be a smart phone 1871. Smart phone 1871 has a touch sensitive display 1873 that displays icons or tiles or other user input mechanisms 1875. Mechanisms 1875 can be used by a user to run applications, make calls, perform data transfer operations, etc. In general, smart phone 1871 is built on a mobile operating system and offers more advanced computing capability and connectivity than a feature phone. Note that other forms of the devices are possible.

However, while FIG. 19 illustrates an embodiment where a device 1800 is a smart phone 1871, it is expressly contemplated that a display may be presented on another computing device.

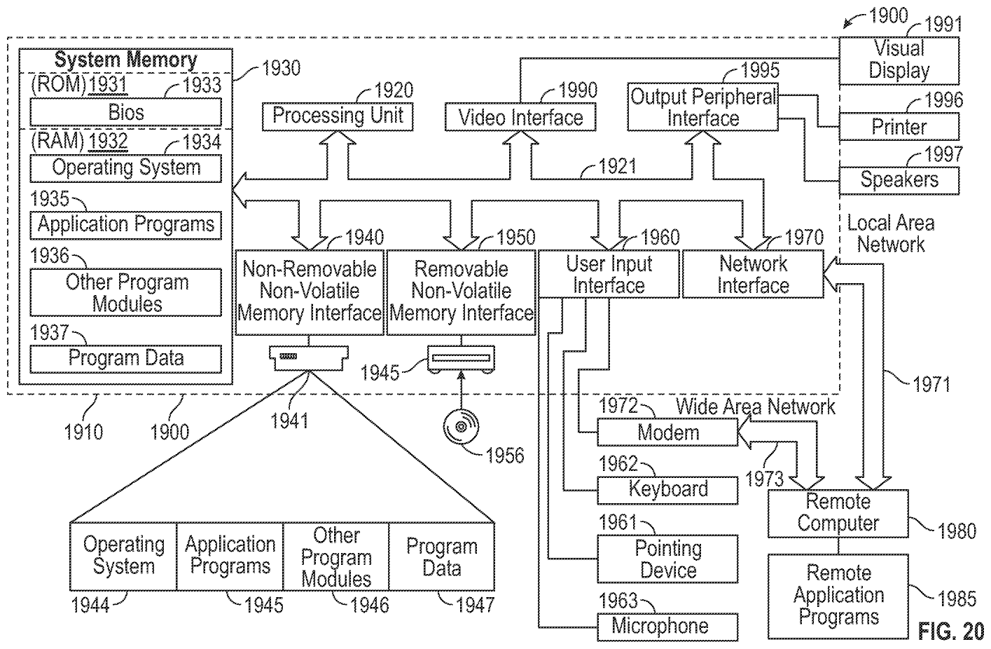

FIG. 20 is one example of a computing environment in which elements of systems and methods described herein, or parts of them (for example), can be deployed. With reference to FIG. 20, an example system for implementing some embodiments includes a general-purpose computing device in the form of a computer 1910. Components of computer 1910 may include, but are not limited to, a processing unit 1920 (which can comprise a processor), a system memory 1930, and a system bus 1921 that couples various system components including the system memory to the processing unit 1920. The system bus 1921 may be any of several types of bus structures including a memory bus or memory controller, a peripheral bus, and a local bus using any of a variety of bus architectures. Memory and programs described with respect to systems and methods described herein can be deployed in corresponding portions of FIG. 20.

Computer 1910 typically includes a variety of computer readable media. Computer readable media can be any available media that can be accessed by computer 1910 and includes both volatile/nonvolatile media and removable/non-removable media. By way of example, and not limitation, computer readable media may comprise computer storage media and communication media. Computer storage media is different from, and does not include, a modulated data signal or carrier wave. It includes hardware storage media including both volatile/nonvolatile and removable/non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computer 1910. Communication media may embody computer readable instructions, data structures, program modules or other data in a transport mechanism and includes any information delivery media. The term “modulated data signal” means a signal that has one or more of its characteristics set or changed in such a manner as to encode information in the signal.

The system memory 1930 includes computer storage media in the form of volatile and/or nonvolatile memory such as read only memory (ROM) 1931 and random-access memory (RAM) 1932. A basic input/output system 1933 (BIOS) containing the basic routines that help to transfer information between elements within computer 1710, such as during start-up, is typically stored in ROM 1931. RAM 1932 typically contains data and/or program modules that are immediately accessible to and/or presently being operated on by processing unit 1920. By way of example, and not limitation, FIG. 19 illustrates operating system 1934, application programs 1935, other program modules 1936, and program data 1937.

The computer 1910 may also include other removable/non-removable and volatile/nonvolatile computer storage media. By way of example only, FIG. 20 illustrates a hard disk drive 1941 that reads from or writes to non-removable, nonvolatile magnetic media, nonvolatile magnetic disk 1952, an optical disk drive 1955, and nonvolatile optical disk 1956. The hard disk drive 1941 is typically connected to the system bus 1921 through a non-removable memory interface such as interface 1940, and optical disk drive 1955 are typically connected to the system bus 1921 by a removable memory interface, such as interface 1950.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (e.g., ASICs), Application-specific Standard Products (e.g., ASSPs), System-on-a-chip systems (SOCs), Complex Programmable Logic Devices (CPLDs), etc.

The drives and their associated computer storage media discussed above and illustrated in FIG. 20, provide storage of computer readable instructions, data structures, program modules and other data for the computer 1910. In FIG. 20, for example, hard disk drive 1941 is illustrated as storing operating system 1944, application programs 1945, other program modules 1946, and program data 1947. Note that these components can either be the same as or different from operating system 1934, application programs 1935, other program modules 1936, and program data 1937.

A user may enter commands and information into the computer 1910 through input devices such as a keyboard 1962, a microphone 1963, and a pointing device 1961, such as a mouse, trackball or touch pad. Other input devices (not shown) may include a joystick, game pad, satellite receiver, scanner, or the like. These and other input devices are often connected to the processing unit 1920 through a user input interface 1960 that is coupled to the system bus but may be connected by other interface and bus structures. A visual display 1991 or other type of display device is also connected to the system bus 1921 via an interface, such as a video interface 1990. In addition to the monitor, computers may also include other peripheral output devices such as speakers 1997 and printer 1996, which may be connected through an output peripheral interface 1995.

The computer 1910 is operated in a networked environment using logical connections, such as a Local Area Network (LAN) or Wide Area Network (WAN) to one or more remote computers, such as a remote computer 1980.

When used in a LAN networking environment, the computer 1910 is connected to the LAN 1971 through a network interface or adapter 1970. When used in a WAN networking environment, the computer 1910 typically includes a modem 1972 or other means for establishing communications over the WAN 1973, such as the Internet. In a networked environment, program modules may be stored in a remote memory storage device. FIG. 20 illustrates, for example, that remote application programs 1985 can reside on remote computer 1980.

In the present detailed description of the preferred embodiments, reference is made to the accompanying drawings, which illustrate specific embodiments in which the invention may be practiced. The illustrated embodiments are not intended to be exhaustive of all embodiments according to the invention. It is to be understood that other embodiments may be utilized and structural or logical changes may be made without departing from the scope of the present invention. The following detailed description, therefore, is not to be taken in a limiting sense, and the scope of the present invention is defined by the appended claims.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “proximate,” “distal,” “lower,” “upper,” “beneath,” “below,” “above,” and “on top,” if used herein, are utilized for ease of description to describe spatial relationships of an element(s) to another. Such spatially related terms encompass different orientations of the device in use or operation in addition to the particular orientations depicted in the figures and described herein. For example, if an object depicted in the figures is turned over or flipped over, portions previously described as below or beneath other elements would then be above or on top of those other elements.

As used herein, when an element, component, or layer for example is described as forming a “coincident interface” with, or being “on,” “connected to,” “coupled with,” “stacked on” or “in contact with” another element, component, or layer, it can be directly on, directly connected to, directly coupled with, directly stacked on, in direct contact with, or intervening elements, components or layers may be on, connected, coupled or in contact with the particular element, component, or layer, for example. When an element, component, or layer for example is referred to as being “directly on,” “directly connected to,” “directly coupled with,” or “directly in contact with” another element, there are no intervening elements, components or layers for example. The techniques of this disclosure may be implemented in a wide variety of computer devices, such as servers, laptop computers, desktop computers, notebook computers, tablet computers, hand-held computers, smart phones, and the like. Any components, modules or units have been described to emphasize functional aspects and do not necessarily require realization by different hardware units. The techniques described herein may also be implemented in hardware, software, firmware, or any combination thereof. Any features described as modules, units or components may be implemented together in an integrated logic device or separately as discrete but interoperable logic devices. In some cases, various features may be implemented as an integrated circuit device, such as an integrated circuit chip or chipset. Additionally, although a number of distinct modules have been described throughout this description, many of which perform unique functions, all the functions of all of the modules may be combined into a single module, or even split into further additional modules. The modules described herein are only exemplary and have been described as such for better ease of understanding.

If implemented in software, the techniques may be realized at least in part by a computer-readable medium comprising instructions that, when executed in a processor, performs one or more of the methods described above. The computer-readable medium may comprise a tangible computer-readable storage medium and may form part of a computer program product, which may include packaging materials. The computer-readable storage medium may comprise random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The computer-readable storage medium may also comprise a non-volatile storage device, such as a hard-disk, magnetic tape, a compact disk (CD), digital versatile disk (DVD), Blu-ray disk, holographic data storage media, or other non-volatile storage device.

The term “processor,” as used herein may refer to any of the foregoing structure or any other structure suitable for implementation of the techniques described herein. In addition, in some aspects, the functionality described herein may be provided within dedicated software modules or hardware modules configured for performing the techniques of this disclosure. Even if implemented in software, the techniques may use hardware such as a processor to execute the software, and a memory to store the software. In any such cases, the computers described herein may define a specific machine that is capable of executing the specific functions described herein. Also, the techniques could be fully implemented in one or more circuits or logic elements, which could also be considered a processor.

An electrical property sensor is presented that includes a printed circuit board with a first face separated from a second face by a thickness, the first face having a length and a width. The sensor also includes an aperture extending from a first face of the printed circuit board to a second face of the printed circuit board. The aperture includes a receiving electrode and a transmitting electrode. When a fluid flows through the aperture and a voltage is provided at the transmitting electrode, a current flow is measured at the receiving electrode.

The sensor may be implemented such that the current flow is convertible to an electrical property value for the fluid.

The sensor may be implemented such that the electrical property includes an impedance value, a conductivity value, or a dielectric constant signal.

The sensor may be implemented such that the aperture is parallel to the length and perpendicular to the width.

The sensor may be implemented such that the aperture is angled with respect to the length.

The sensor may be implemented such that the printed circuit board is positioned perpendicularly to the fluid flow.

The sensor may be implemented such that the receiving electrode and the transmitting electrode each have an electrode width that is substantially the thickness.

The sensor may be implemented such that the receiving electrode and the transmitting electrode each have an electrode length less than an aperture length.

The sensor may be implemented such that the receiving electrode includes a metal.

The sensor may be implemented such that the transmitting electrode also includes the metal.

The sensor may be implemented such that the metal includes copper, aluminum, gold, silver or combinations thereof.

The sensor may be implemented such that and further including a gold coating over the copper.

The sensor may be implemented such that the aperture is a first aperture, and the sensor also includes a second aperture extending from the first face of the printed circuit board to the second face of the printed circuit board, the second aperture having a second receiving electrode and a second transmitting electrode. The fluid flow is a first portion of a fluid flow and, when a second portion of the fluid flows through the second aperture, a second impedance signal is generated using the second transmitting and receiving electrodes.

The sensor may be implemented such that the second receiving electrode is decoupled from the first receiving electrode, such that the impedance signal and the second impedance signal differ.

The sensor may be implemented such that the printed circuit board is a standard printed circuit board.

The sensor may be implemented such that the sensor is part of a sensor stack composed of the impedance sensor and a second impedance sensor.

The sensor may be implemented such that it has a temperature sensor.

The sensor may be implemented such that the temperature sensor is electrically isolated from the fluid flow.

The sensor may be implemented such that the temperature sensor is isolated by a layer of varnish or epoxy-resin based adhesive.

The sensor may be implemented such that the temperature sensor is within a second aperture.

The sensor may be implemented such that the temperature sensor is coplanar with the receiving electrode and the transmitting electrode.

The sensor may be implemented such that the aperture is closed on a first end and open on a second end.

The sensor may be implemented such that wherein a portion of an exterior of the PCB is metallized.

The sensor may be implemented such that a corner of the PCB is metallized.

The sensor may be implemented such that the PCB is an additively manufactured PCB.

A sensing system is presented that includes a fluid channel through which a fluid flows and a sensor within the fluid channel. The sensor includes a printed circuit board (PCB), an aperture within the PCB including a receiving electrode spaced apart from a transmitting electrode. The fluid flows through the aperture in direct contact with the transmitting electrode and the receiving electrode. When a voltage is applied to the transmitting electrode, a current is received at the receiving electrode. The sensor also includes a communication component that communicates a calculated electrical parameter for the fluid, the electrical parameter is calculated based on the received current.

The system may be implemented such that the fluid channel includes a mixing chamber that receives a first component flow and a second component flow.

The system may be implemented such that the sensor is downstream of the mixing chamber.

The system may be implemented such that and further including a second sensor within the fluid channel, the second sensor is upstream of the mixing chamber.

The system may be implemented such that the electrical parameter is an impedance, a conductivity or a dielectric constant.

The system may be implemented such that the electrical parameter is indicative of an air bubble in the fluid flow.

The system may be implemented such that the electrical parameter is indicative of a mixing ratio.

The system may be implemented such that the electrical parameter is indicative of a mixing quality across the fluid flow.

The system may be implemented such that the electrical parameter is indication of a fluid age.

The system may be implemented such that the electrical parameter is indicative of a cure progress.

The system may be implemented such that the transmitting electrode is perpendicular to a surface of the PCB.

The system may be implemented such that the transmitting electrode is aligned with a length of the aperture, and the receiving electrode is parallel to the transmitting electrode.

The system may be implemented such that it includes a second aperture, with a second length, a second width perpendicular to the second length, and a second thickness perpendicular to the second length and width, and the second length is at least three times the second width and the second width is greater than the second thickness.

The system may be implemented such that it includes a second transmitting electrode, within the second aperture, and a second receiving electrode, parallel to the second transmitting electrode, within the aperture.

The system may be implemented such that the second aperture is parallel to the first aperture.

The system may be implemented such that the sensor is a first sensor, and further including a second sensor.

The system may be implemented such that the second sensor is decoupled from the first sensor.

The system may be implemented such that the second sensor is parallel to the first sensor.

The system may be implemented such that and further including a third sensor.

The system may be implemented such that and further including a control signal generator that generates a control signal, based on the conductivity signal.

The system may be implemented such that the control signal is a purge signal.

The system may be implemented such that the control signal is a motor speed.

The system may be implemented such that the transmitting electrode has an electrode length, the aperture has an aperture length, and the aperture length is greater than the electrode length.

The system may be implemented such that the PCB is a first PCB. The sensor also includes a second printed circuit board (PCB), a second aperture within the second PCB including a second receiving electrode spaced apart from a second transmitting electrode, and the fluid flows through the second aperture in direct contact with the second transmitting electrode and the second receiving electrode.

The system may be implemented such that the second aperture is positioned such that the fluid flows through the first aperture before flowing through the second aperture.

The system may be implemented such that the second PCB is coupled to the first PCB.

The system may be implemented such that the second PCB is a two-layer PCB and the first PCB is a four-layer PCB.

The system may be implemented such that the first PCB includes a temperature sensor.

The system may be implemented such that the temperature sensor is electrically isolated from the fluid flow.

The system may be implemented such that the temperature sensor is isolated by a layer of varnish or a layer of epoxy-resin based adhesive.

The system may be implemented such that the PCB includes a temperature sensor.

The system may be implemented such that the temperature sensor is isolated from the fluid flow.

The system may be implemented such that the temperature sensor is isolated by a layer of varnish or a layer of epoxy-resin based adhesive.

The system may be implemented such that the first aperture receives a first fluid flow and the second aperture receives a second fluid flow, and the first and second fluid flows are chemically different.

A dispensing system is presented that includes a mixer that receives a first fluid stream and a second fluid stream and produces a mixture. The system also includes a sensor within a fluid flow stream of the dispensing system. The sensor includes a printed circuit board including a aperture, a transmitting electrode on a first portion of the aperture, a receiving electrode on a second portion of the aperture. The mixture flows through the aperture, contacting the transmitting electrode and receiving electrode, and the sensor generates a sensor signal indicative of the mixture. The system also includes a dispenser that dispense the mixture. The system also includes a communication component that communicates the sensor signal.

The system may be implemented such that mixer is a static mixer.

The system may be implemented such that mixer is an active mixer.

The system may be implemented such that sensor is downstream of the mixer.

The system may be implemented such that sensor is upstream of the mixer and downstream from a first fluid source.

The system may be implemented such that printed circuit board is positioned within the fluid flow stream such that the fluid flows through the aperture.

The system may be implemented such that printed circuit board is perpendicular to the fluid flow.

The system may be implemented such that sensor is a first sensor, positioned downstream of the mixer, and the dispensing system includes a second sensor, positioned upstream of the mixer.

The system may be implemented such that fluid flow includes a first component fluid flow and a second component fluid flow, and the sensor receives both the first component fluid flow and the second component fluid flow.

The system may be implemented such that first fluid flows through the aperture, and the second fluid flows through a second aperture of the printed circuit board, the second aperture includes a second transmitting electrode and a second receiving electrode.

The system may be implemented such that it includes a housing that houses the sensor and physically separates the first fluid flow from the second fluid flow.

The system may be implemented such that second sensor is placed in a first fluid stream, and further including a third sensor, placed in a second fluid stream upstream of the mixer.

The system may be implemented such that aperture is a first aperture, and the printed circuit board includes a second aperture, with a second transmitting electrode and a second receiving electrode.

The system may be implemented such that transmitting electrode is parallel to a length of the aperture, and parallel to the receiving electrode.

The system may be implemented such that it includes an analyzer that receives the sensor signal and provides an indication.

The system may be implemented such that indication includes an age of the first fluid.

The system may be implemented such that analyzer determines the indication by comparing the sensor signal to a stored sensor signal.

The system may be implemented such that indication includes a cure progress indication of the mixture.

The system may be implemented such that indication includes a mix ratio.

The system may be implemented such that it includes an analyzer that receives a first sensor signal from the first sensor, a second sensor signal from the second sensor, and a third sensor signal from the third sensor.

The system may be implemented such that the analyzer provides a mix ratio indication based on the received sensor signals.

The system may be implemented such that the analyzer provides a batch quality indication based on the received sensor signals.

The system may be implemented such that the analyzer provides an age indication based on the received sensor signals.

The system may be implemented such that the indication includes a mix quality across a cross section of the fluid flow.

The system may be implemented such that the analyzer determines the indication by applying a predictive model to the sensor signal.

The system may be implemented such that the indication includes an air bubble indication.

The system may be implemented such that the air bubble indication includes an indication that a sensed conductivity has spiked.

The system may be implemented such that the conductivity spike is greater than a relative threshold.

The system may be implemented such that, based on the indication, a control signal is generated to purge the fluid flow.

The system may be implemented such that, in response to the sensor signal, a control signal is provided to a motor to adjust a motor speed of the motor.

The system may be implemented such that, in response to the sensor signal, a purge is automatically initiated.

The system may be implemented such that it also includes a display component that receives the sensed signal and provides a visual indication of the sensed signal.

The system may be implemented such that the visual indication is a mix quality indication.

The system may be implemented such that the communication component provides the sensed signal to a datastore.

The system may be implemented such that the sensor includes a temperature sensor.

The system may be implemented such that the sensor is coplanar with the receiving and transmitting electrodes.

The system may be implemented such that the temperature sensor is isolated from the fluid flow.

The system may be implemented such that the temperature sensor is isolated by a layer of varnish or a layer of epoxy-resin based adhesive.

The system may be implemented such that the sensor is a first sensor, and further including a second sensor coupled to the first sensor.

The system may be implemented such that the coupling includes a conductive material.

The system may be implemented such that the conductive material is solder.

The system may be implemented such that the second sensor is coupled such that the fluid flows through the first aperture before flowing through a second aperture, the second sensor includes the second aperture.

The system may be implemented such that the first sensor is a four-layer PCB and the second sensor is a two-layer PCB.

The system may be implemented such that the PCB is non-orthogonally angled with respect to the fluid flow.

A method of measuring a mixture quality is presented that includes providing a first fluid and a second fluid to a mixer. The method also includes receiving a mixture from the mixer, and causing a portion of the mixture to pass through a sensor, the sensor includes a printed circuit board with an aperture that receives the mixture portion such that the mixture portion directly contacts a transmitting electrode and a receiving electrode. The method also includes generating a sensor signal indicative of the mixture quality.

The method may be implemented such that the sensor fills a majority of an area through which the mixture flows, such that the mixture flows through the aperture.

The method may be implemented such that the sensor includes a plurality of apertures, and the mixture flows through the plurality of apertures such that a first mixture portion flows through a first aperture and a second mixture portion flows through a second aperture.

The method may be implemented such that it also includes receiving a first electrical parameter signal from a first electrode pair associated with the first aperture. It also includes receiving a second electrical parameter signal from a second electrode pair associated with the second aperture. The sensor signal is based on the first and second electrical parameter signals, and the first and second electrical parameter signals are impedance signals, conductivity signals or dielectric constant signals.

The method may be implemented such that the first electrode pair is spaced apart, and decoupled, from the second electrode pair.

The method may be implemented such that the first electrical parameter signal differs from the second electrical parameter signal and the method further includes providing a mixing quality indication based on a comparison of the first and second electrical parameter signal.

The method may be implemented such that the includes a comparison of intra-signal statistical values and intersignal statistical values of the first and second conductivity signals.

The method may be implemented such that intra-signal statistical values include a mean, a variance, and a covariance.

The method may be implemented such that it also includes applying a predictive model to, based on the sensor signal, generate a prediction regarding the mixture.

The method may be implemented such that the prediction is a predicted purge time.

The method may be implemented such that it also includes detecting an air bubble in the provided first fluid and removing the air bubble from the first fluid.

The method may be implemented such that the air bubble is detected by the sensor The method may be implemented such that removing includes generating a purge signal that causes a valve to open such that the bubble is diverted.

The method may be implemented such that it includes verifying that the air bubble was removed.

The method may be implemented such that verifying includes passing the first fluid through a second sensor, downstream from the sensor.

The method may be implemented such that it includes providing a third fluid to the mixer.

The method may be implemented such that the first electrode pair receives the first fluid and the second electrode pair receives the second component.

The method may be implemented such that the sensor includes a housing that maintains separation between the first and second fluids while flowing through the first and second electrode pairs.

A bubble detection system for a material dispensing system is presented that includes a sensor system in fluid contact with a flowing material that generates a signal. The sensor includes a printed circuit board with an aperture extending through a thickness of the printed circuit board from a first face to a second face. The sensor also includes a transmitting electrode, on a first portion of the aperture, that transmits a voltage. The sensor also includes a receiving electrode, on a second portion of the aperture, that receives a conducted electric current. The sensor also includes an electric parameter calculator that generates an impedance, a conductivity or a dielectric constant periodically based on the received current. The sensor also includes a conductivity analyzer that: receives the calculated electric parameter and detects a spike, compares the spike to a threshold, and if the spike is outside of the threshold, and generates a bubble detection indication.

The bubble detection system may be implemented such that it also includes a communication component that communicates the bubble detection indication.

The bubble detection system may be implemented such that the bubble detection indication includes a purge command, and the communication component communicates the purge command to a valve controller.

The bubble detection system may be implemented such that the threshold is a relative threshold based on previously received signals.

The bubble detection system may be implemented such that the aperture is a first aperture, and the printed circuit board has a plurality of apertures, each with a transmitting electrode and a receiving electrode, and the plurality of apertures are coplanar.

The bubble detection system may be implemented such that each of the plurality of apertures are parallel to each other.

The bubble detection system may be implemented such that each of the plurality of apertures are parallel to a length of the printed circuit board, the length is a longest edge of the printed circuit board.

The bubble detection system may be implemented such that each of the apertures has a length and a width, and the length is at least three times as long as the width.

The bubble detection system may be implemented such that a fluid flows between the transmitting and receiving electrodes.

The bubble detection system may be implemented such that the aperture contains a first end and a second end, and wherein, at each end, the receiving and transmitting electrodes are decoupled.

The bubble detection system may be implemented such that the PCB is a first PCB, and further including a second PCB stacked above or below the first PCB.

The bubble detection system may be implemented such that the first PCB is mechanically coupled to the second PCB.

The bubble detection system may be implemented such that the mechanical coupling includes solder.

The bubble detection system may be implemented such that the first PCB is a four-layer PCB and the second PCB is a two-layer PCB.

The bubble detection system may be implemented such that it has a temperature sensor.

A method of removing a bubble from a material dispensing system is presented that includes detecting, with a sensor, an indication of an air bubble in a fluid flow. The sensor includes a printed circuit board with a aperture extending from a first point on the printed circuit board to a second point on the printed circuit board, and the aperture extends through a thickness of the printed circuit board, a transmitting electrode on a first surface of the aperture, a receiving electrode on a second surface of the aperture, opposite the first surface of the aperture, and the printed circuit board is configured to be positioned in a fluid line such that the fluid flow is forced through the aperture. The method also includes receiving a sensed electrical parameter value from the sensor, comparing the sensed electrical parameter value to a threshold and, if a conductivity spike is detected based on the comparison, generating a command to purge the fluid line, and communicating the purge command to a valve controller.

The method may be implemented such that the threshold is a relative threshold based on previously received sensor signals.

The method may be implemented such that, the printed circuit board includes a plurality of apertures, and the plurality of apertures are spaced apart on the printed circuit board such that a first portion of fluid travels through a first aperture, and a second portion of fluid travels through a second aperture.

The method may be implemented such that the sensor is a first sensor, and further includes detecting, with a second sensor downstream from the first sensor, that the air bubble has been removed.

A method of forming a sensor is presented that includes creating an aperture in a printed circuit board, the aperture has a length and a width and a thickness, the thickness extends through the printed circuit board and adhering a first electrode and second electrode within the aperture.

The method may be implemented such that adhering includes: metallizing the interior surface of the aperture and decoupling the first electrode from the second electrode.

The method may be implemented such that decoupling includes removing a portion of the metallized surface.

The method may be implemented such that removing the portion of the metallized surface includes drilling out a portion of the metallized surface.

The method may be implemented such that it includes drilling out a second portion of the metallized surface.

The method may be implemented such that the aperture is a first aperture, and further includes: creating a second aperture in the printed circuit board, the second aperture has the length, the width, and the thickness, and the second aperture is spaced apart from the first aperture.

The method may be implemented such that it includes creating a third aperture in the printed circuit board, the third aperture has the length, the width, and the thickness, and the third aperture is spaced apart from the aperture and the first, second and third apertures are spaced apart on the printed circuit board.

The method may be implemented such that a first space, between the first and second apertures, is the same as a second space, between the second and third apertures.

The method may be implemented such that a first space, between the first and second apertures, is different from a second space, between the second and third apertures.

The method may be implemented such that metallizing includes applying a layer of copper to the interior surface of the aperture.

The method may be implemented such that it also includes creating a second aperture in a second printed circuit board, adhering a third electrode and a fourth electrode within the second aperture, and coupling the second printed circuit board to the first circuit board.

The method may be implemented such that the second printed circuit board is a two-layer PCB and the first printed circuit board is a four-layer PCB.

A material dispensing system is presented that includes a mixer with a first material inlet,
a second material inlet, and a material outlet, a first sensor, located at the first material inlet, a second sensor, located at the second inlet; a third sensor, located at the material outlet, and the first, second and third sensor are in fluid contact with a material flowing through the material dispensing system, a material analyzer that receives a first sensor signal from the first sensor, a second sensor signal from the second sensor, and a third sensor signal from the third sensor and provides an indication, and a communication component that communicates the indication to a second device.

The material dispensing system may be implemented such that the first sensor, second sensor and third sensor all include a printed circuit board.

The material dispensing system may be implemented such that the first sensor includes an aperture, and the aperture includes a transmitting electrode and a receiving electrode, and the transmitting electrode and the receiving electrode are in fluid contact with the material flowing through the material dispensing system.

The material dispensing system may be implemented such that the first sensor includes a second aperture, coplanar with the aperture, and the second aperture includes a second transmitting electrode and a second receiving electrode.

The material dispensing system may be implemented such that the first sensor includes a temperature sensor.

The material dispensing system may be implemented such that the temperature sensor is coplanar with the transmitting electrode and receiving electrode.

The material dispensing system may be implemented such that the first sensor includes a printed circuit board, and the aperture is part of the printed circuit board.

The material dispensing system may be implemented such that the printed circuit board is a first printed circuit board, and the first sensor includes a second printed circuit board, coupled to the first circuit board.

The material dispensing system may be implemented such that the material analyzer is a mixing analyzer and the indication is a mixing indication.

The material dispensing system may be implemented such that the mixing indication is a real-time mixing ratio.

The material dispensing system may be implemented such that the mixing indication is an indication of incomplete mixing.

The material dispensing system may be implemented such that the mixing indication is a visual, haptic or audio alert.

The material dispensing system may be implemented such that the material analyzer is a curing analyzer and the indication is a cure indication.

The material dispensing system may be implemented such that the cure indication is an indication that a flow line should be purged.

The material dispensing system may be implemented such that the cure indication is an indication that a purge of curing material is complete.

The material dispensing system may be implemented such that the material analyzer is a bubble detector and the indication is a detected bubble.

The material dispensing system may be implemented such that the material analyzer is a composition drift analyzer and the indication is a detected change in composition.

The material dispensing system may be implemented such that the material analyzer is a start up analyzer, and the indication is a mixture ratio stabilization indication.

The material dispensing system may be implemented such that the material analyzer is a homogeneity analyzer and the indication is an indication of a nonhomogeneous fluid flow.

The material dispensing system may be implemented such that the indication includes a command, and the communication component provides the command to the second device automatically, such that the command is implemented automatically by the second device.

The material dispensing system may be implemented such that the command is a motor speed signal and the second device is a motor controller for a pump providing a first material to the first material inlet.

The material dispensing system may be implemented such that the command is a valve control command, and the second device is a valve controller.

The material dispensing system may be implemented such that the valve control command is a valve open or valve close command.

The material dispensing system may be implemented such that the indication includes a graphical user interface update, and the second device includes a display component that updates a graphical user interface automatically when the user interface update is received.

The material dispensing system may be implemented such that the graphical user interface update includes a real-time calculated mix ratio and a target mix ratio.

The material dispensing system may be implemented such that the graphical user interface includes the indication.

The material dispensing system may be implemented such that it includes a PCB board, the PCB board includes the first and second sensor.

The material dispensing system may be implemented such that the first and second sensors are decoupled.

The material dispensing system may be implemented such that it includes a separation component that separates a first fluid, flowing through the first sensor, from a second component, flowing through the second sensor.

An electrical parameter sensor is presented that includes a first printed circuit board including a first aperture, a first transmitting electrode within the first aperture, and a first receiving electrode within the aperture, and a fluid flows through the first aperture. The system also includes a second printed circuit board including a second aperture, a second transmitting electrode within the second aperture, and a second receiving electrode within the second aperture, and the fluid flows through the second aperture. The first printed circuit board is positioned on top of the second printed circuit board such that the first transmitting electrode is aligned with the second transmitting electrode.

The electrical parameter sensor may be implemented such that the first and second transmitting electrodes are electrically connected to each other and in direct contact with a material flow.

The electrical parameter sensor may be implemented such that the first and second receiving electrodes are electrically connected to each other and in direct contact with a material flow.

The electrical parameter sensor may be implemented such that the electrical parameter is a conductivity, an impedance or a dielectric constant.

The electrical parameter sensor may be implemented such that the aperture is closed on both a first end and a second end.

The electrical parameter sensor may be implemented such that the first printed circuit board is a four-layer printed circuit board with an edge connector interface.

The electrical parameter sensor may be implemented such that the second printed circuit board is a second layer printed circuit board.

The electrical parameter sensor may be implemented such that it has a temperature sensor.

The electrical parameter sensor may be implemented such that the temperature sensor is electrically isolated from a material flow.

The electrical parameter sensor may be implemented such that the temperature sensor is coplanar with the first transmitting electrode and the first receiving electrode.

The electrical parameter sensor may be implemented such that the first and second printed circuit boards are mechanically coupled.

The electrical parameter sensor may be implemented such that the first and second printed circuit boards are soldered together.

The electrical parameter sensor may be implemented such that and further including a sealing ring that engages with a material flow line.

The electrical parameter sensor may be implemented such that the sensor generates a first signal from the first transmitting and receiving electrodes, and the sensor generates a second signal from a third transmitting electrode and a third receiving electrode.

The electrical parameter sensor may be implemented such that the third transmitting electrode and third receiving electrode are coplanar with the first transmitting electrode and first receiving electrode.

The electrical parameter sensor may be implemented such that the aperture is closed on a first end and open on a second end.

### EXAMPLES

These examples are merely for illustrative purposes and are not meant to be overly limiting on the scope of the appended claims. Notwithstanding that the numerical ranges and parameters setting forth the broad scope of the present disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed considering the number of reported significant digits and by applying ordinary rounding.

Unless otherwise noted, all chemicals used in the examples can be obtained from the noted suppliers. Adhesives used in example embodiments can include the adhesives described below.

### Example 1: PCB Sensor Design

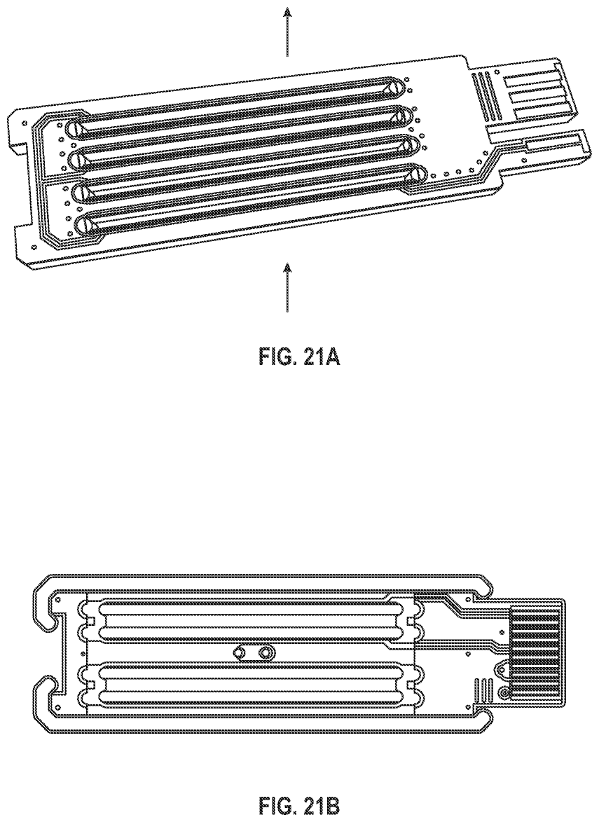

A sensor as illustrated in FIG. 21A was designed. First the holes for the electrodes and the temperature sensor were milled out. After drilling holes or milling slots in the PCB, the PCB was chemically coated with copper. This coating happened in tanks filled with liquid chemicals. After this process, a 1 μm thin layer of copper covered the inside of the milled apertures. To increase the thickness of this layer, additional copper was added by galvanic copper deposition. After this step, a 20 μm thick layer of copper covered the inside of the holes and slots. There were two electrically conductive surfaces facing to each other, but they were electrically connected together at both ends of the slots. FIG. 21B illustrates the PCB sensor at this point in the process.

To get two electrically separate electrodes, the connections at the ends of the slots were removed by drilling or milling holes or slots at the end of the plated slots. This way the copper plating of the plated slots were removed in the curved area at the ends.

### Example 2: PCB Sensor and Sensor Stack

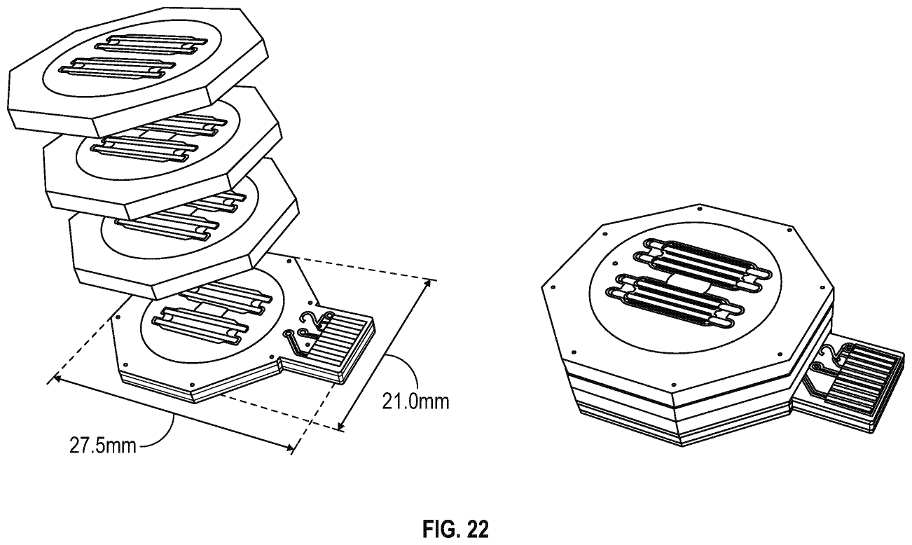

A sensor as illustrated in FIG. 22, a sensor stack was designed with the illustrated dimensions.

### Examples 3: Metering Pump System Sensor Application for Continuous Dispensing System

A system (PK2D variable ratio positive displacement metering pumps from Fluidic Systems, Santa Anna, CA) provided continuous flow of a material (3M™ Scotch-Weld™ Epoxy Adhesive 2216NS, two-part epoxy adhesive from 3M, St. Paul, MN) to a dispense valve. A mix nozzle (Model MC-13-24, from Sulzer Mixpac, Haag, Switzerland) was attached to the dispense valve, approximately 3 meters from each of the metering pumps. A sensor (as illustrated in FIG. 21A) was attached to the end of the mix nozzle using a threaded adaptor to provide a secure connection. Conductivity and temperature signals were received and graphed over time for input variables measured.

A pressure sensor was located at the exterior of each positive displacement pump. Temperature, conductivity, and pressure signals could all be all captured and displayed simultaneously.

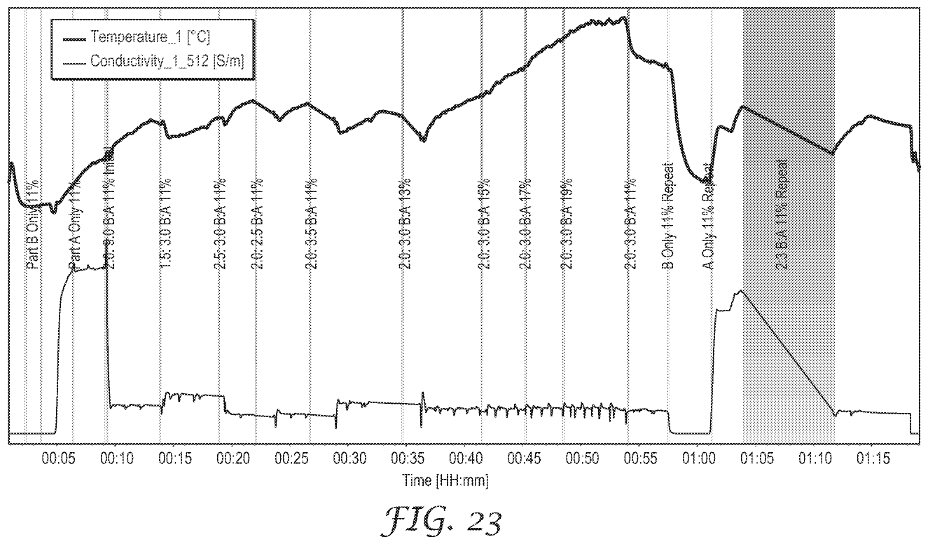

Using the system described above, a set of experiments was conducted which varied the ratio and flow rate of the material for Part A and Part B to form a resin mixture. Part A of the resin mixture was an Accelerant and Part B of the resin mixture was a base. In real-time, temperature and conductivity signals were collected, recorded, and plotted vs. time and shown in FIG. 23. FIG. 23 shows when a flow rate of the resin mixture was set to 11% initially and then shows how altering the ratios of Part A and Part B of the resin mixture impacted conductivity and temperature. FIG. 23 also shows the temperature and conductivity data plots of a second set of experiments that was conducted where the ratio was held at 3:2 Part A:Part B with flow rate increasing. Small spikes were observed in the conductivity readings throughout the changes in different flow and ratio conditions.

### Example 4: Metering Pump System Sensor Application for Continuous Dispensing

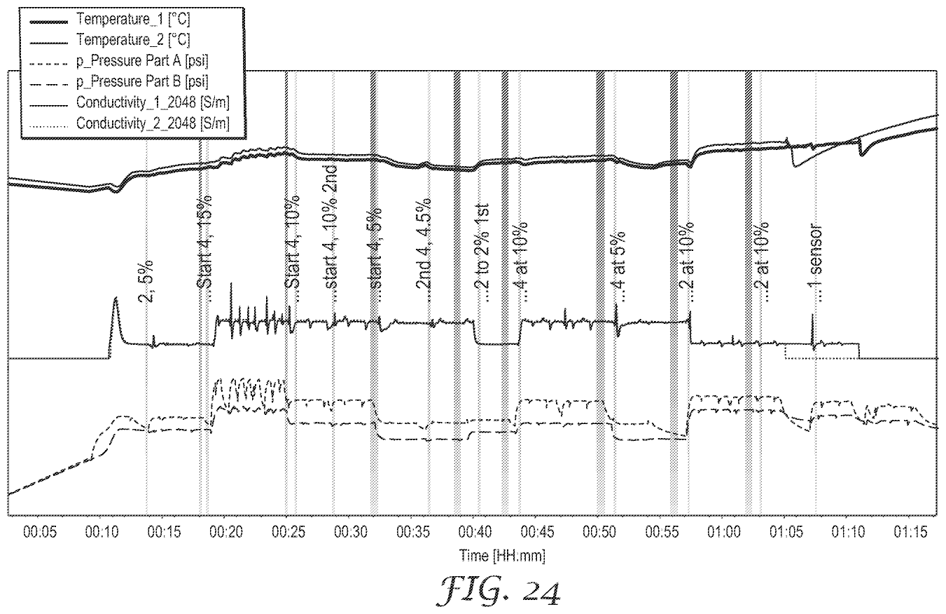

The same system described above in Example 3 was used to complete another set of experiments that were conducted now with the inclusion of two sensors in series where the resin mixture ratio and flow rate were varied at a fixed temperature while pressure measurements were added to the data collection. The purpose of the two sensors in series was to determine variability between sensors. This was repeated with three other pairs of sensors. Temperature, conductivity, and pressure measurements vs. time were collected, recorded, and plotted vs. time and one pair of sensors is shown in FIG. 24. With the addition of pressure measurements being taken and recorded simultaneously to conductivity measurements and those two sets of measurements being able to be compared, it was shown that the spike changes in conductivity are due to a winking in the metering pump upon changing direction. In the experiments conducted, Part A material appeared to be the primary driver of the spikes. An approximate 8 second delay between the pressure winks and the conductivity spikes was consistently observed. Including the pressure measurements in the data collection allows for an explanation of spiking phenomenon. This is opposed to a surge or other change in the relative materials (i.e. change in ratio or other in homogeneities like air bubbles in the resin systems).

1. An electrical property sensor comprising:
a printed circuit board with a first face separated from a second face by a thickness, the first face having a length and a width;
an aperture extending from a first face of the printed circuit board to a second face of the printed circuit board, the aperture comprising a receiving electrode and a transmitting electrode; and
wherein, when a fluid flows through the aperture and a voltage is provided at the transmitting electrode, a current flow is measured at the receiving electrode.

2. The sensor of claim 1, wherein the current flow is convertible to an impedance value, a conductivity value, or a dielectric constant signal.

3. The sensor of claim 1, wherein the aperture is parallel to the length and perpendicular to the width.

4. The sensor of claim 1, wherein the receiving electrode and the transmitting electrode each have an electrode width that is substantially the thickness.

5. The sensor of claim 1, wherein the receiving electrode and the transmitting electrode each have an electrode length less than an aperture length.

6. The sensor of claim 1, wherein the receiving electrode comprises a metal.

7. The sensor of claim 6, wherein the transmitting electrode also comprises the metal.

8. The sensor of claim 1, wherein the aperture is a first aperture, and wherein the sensor also comprises:
a second aperture extending from the first face of the printed circuit board to the second face of the printed circuit board, the second aperture comprising a second receiving electrode and a second transmitting electrode;
wherein the fluid flow is a first portion of a fluid flow and, when a second portion of the fluid flows through the second aperture, a second impedance signal is generated using the second transmitting and receiving electrodes.

9. The sensor of claim 9, wherein the second receiving electrode is decoupled from the first receiving electrode, such that the impedance signal and the second impedance signal differ.

10. The sensor of claim 1, and further comprising a temperature sensor.

11. The sensor of claim 10, wherein the temperature sensor is electrically isolated from the fluid flow.

12. A sensing system comprising:
a fluid channel through which a fluid flows;
a sensor within the fluid channel, the sensor comprising:
a printed circuit board (PCB);
a aperture within the PCB comprising a receiving electrode spaced apart from a transmitting electrode; and
wherein the fluid flows through the aperture in direct contact with the transmitting electrode and the receiving electrode and wherein, when a voltage is applied to the transmitting electrode, a current is received at the receiving electrode; and
a communication component that communicates a calculated electrical parameter for the fluid, wherein the electrical parameter is calculated based on the received current and wherein the electrical parameter is an impedance, a conductivity or a dielectric constant.

13. The system of claim 12, wherein the fluid channel comprises a mixing chamber that receives a first component flow and a second component flow.

14. The system of claim 13, wherein the sensor is downstream of the mixing chamber.

15. The system of claim 14, and further comprising a second sensor within the fluid channel, wherein the second sensor is upstream of the mixing chamber.

16. The system of claim 15, wherein the electrical parameter is indicative of an air bubble in the fluid flow, a mixing ratio, of a mixing quality across the fluid flow, a fluid age, or a cure progress.

17. The system of claim 12, wherein the transmitting electrode is aligned with a length of the aperture, and wherein the receiving electrode is parallel to the transmitting electrode.

18. The system of claim 12, and further comprising a control signal generator that generates a control signal, based on the conductivity signal.

19. The system of claim 18, wherein the control signal is a purge signal or a motor speed.

20-27. (canceled)

28. A method of forming a sensor, the method comprising:
creating an aperture in a printed circuit board, wherein the aperture has a length and a width and a thickness, wherein the thickness extends through the printed circuit board; and
adhering a first electrode and second electrode within the aperture.

29-36. (canceled)
